(19) United States
(12) Patent Application Publication
(10) Pub. No.: US 2019/0023817 A1
(43) Pub. Date: Jan. 24, 2019

(54) Ferroelectric polymers from dehydrofluorinated PVDF

(71) Applicant: THE REGENTS OF THE UNIVERSITY OF MICHIGAN, Ann Arbor, MI (US)

(72) Inventor: Henry A. Sodano, Ann Arbor, MI (US)

(21) Appl. No.: 15/998,468

(22) Filed: Aug. 15, 2018

Related U.S. Application Data
(63) Continuation-in-part of application No. 15/434,442, filed on Feb. 16, 2017.

(51) Int. Cl. C08F 8/26; C08F 14/22; H01L 41/193; H01L 41/45

(52) U.S. Cl. CPC C08F 8/26; H01L 41/45; H01L 41/193; C08F 14/22

(57) ABSTRACT

A method for synthesizing a piezoelectric material is provided. The method includes dehydrofluorinating a fluoropolymer precursor by incubating the fluoropolymer precursor in the presence of a base, wherein the fluoropolymer precursor comprises poly(vinylidene fluoride) or a copolymer of vinylidene fluoride; and isolating an at least partially dehydrofluorinated fluoropolymer solid having β-phase and that exhibits melt flow processability at a temperature of greater than or equal to about 150° C. The at least partially dehydrofluorinated fluoropolymer solid is capable of forming a solid piezoelectric fluoropolymer material having β-phase in an amount sufficient to exhibit a piezoelectric strain coefficient d₃₁ absolute value of greater than or equal to about 25 pm/V.

### CROSS-REFERENCE TO RELATED APPLICATIONS

This application is a continuation-in-part of U.S. patent application Ser. No. 15/434,442, filed on Feb. 16, 2017. The entire disclosure of the above application is incorporated herein by reference.

### GOVERNMENT RIGHTS

This invention was made with government support under FA9550-16-1-0087 awarded by the Air Force Office of Scientific Research. The government has certain rights in the invention.

### FIELD

The present disclosure relates to ferroelectric polymers and, more particularly, relates to ferroelectric polymers formed from dehydrofluorinated poly (vinylidene fluoride) PVDF.

### BACKGROUND

This section provides background information related to the present disclosure which is not necessarily prior art. This section also provides a general summary of the disclosure, and is not a comprehensive disclosure of its full scope or all of its features.

The present invention concerns a material that displays piezoelectric and ferroelectric properties. Piezoelectricity refers to the accumulation of an electric charge due to the application of mechanical stress. These materials also exhibit the reverse effect: when subject to an electrical charge, they will undergo mechanical strain.

Ferroelectric materials contain a permanent dipole which allows them to maintain a polar electric field when they are not subjected to an external field. All ferroelectric materials display piezoelectricity. There is interest in using polymers to create such materials due to the fact that polymers are lightweight, low cost, and relatively easy to process as compared to intermetallic compounds. Piezoelectric polymers, such as poly (vinylidene fluoride) (PVDF) and its copolymers, have the potential to achieve large strains and high working energy density under external electrical fields, which is very promising for biomimetic actuators and artificial muscle technologies.

Poly (vinylidene fluoride) (PVDF) is a polymer that shows promise as a ferroelectric materials. In addition to an amorphous phase, PVDF can crystallize into multiple phases with different chain conformations known as α, β, and γ-phase. Only the β-phase has strong ferroelectric and piezoelectric properties because of its planar conformation and high dipole density.

Previous methods to produce ferroelectric PVDF rely on combinations of annealing, controlled solvent evaporation, and uni-axial stretching of a sample. These methods yield a final product that lacks thermal stability or contains an insufficient proportion of the β-phase.

The ferroelectric β-phase has only been obtained through use of a drawing process (typically 300-400% elongation). Thus only thin films can be effectively produced, placing limits on the potential application space and transducer design.

### SUMMARY

This section provides a general summary of the disclosure, and is not a comprehensive disclosure of its full scope or all of its features.

In various aspects, the current technology provides a method for synthesizing a piezoelectric material. The method includes dehydrofluorinating a fluoropolymer precursor by incubating the fluoropolymer precursor in the presence of a base, wherein the fluoropolymer precursor comprises poly(vinylidene fluoride) or a copolymer of vinylidene fluoride; and isolating an at least partially dehydrofluorinated fluoropolymer solid having β-phase and that exhibits melt flow processability at a temperature of greater than or equal to about 150° C. The at least partially dehydrofluorinated fluoropolymer solid is capable of forming a solid piezoelectric fluoropolymer material having β-phase in an amount sufficient to exhibit a piezoelectric strain coefficient d₃₁ absolute value of greater than or equal to about 25 pm/V.

In one aspect, during the dehydrofluorinating, the fluoropolymer precursor and the base are combined with a solvent selected from the group consisting of N-methyl pyrrolidone (NMP), dimethylsulfoxide (DMSO), N,N-dimethylformamide (DMF), methyl ethyl ketone (MEK), tetrahydrofuran (THF), N,N-dimethylacetamide (DMAc), and combinations thereof.

In one aspect, the dehydrofluorinating forms an at least partially dehydrofluorinated reaction product present in the solvent, and the isolating further includes precipitating the at least partially dehydrofluorinated reaction product from the liquid admixture and recrystallizing the at least partially dehydrofluorinated reaction product to form the at least partially dehydrofluorinated fluoropolymer solid.

In one aspect, during the dehydrofluorinating, the fluoropolymer precursor is a solid fluoropolymer precursor that is suspended in a liquid admixture comprising the base.

In one aspect, the dehydrofluorinating forms the at least partially dehydrofluorinated fluoropolymer solid from the solid fluoropolymer precursor, and the isolating further includes removing the at least partially dehydrofluorinated fluoropolymer solid from the liquid admixture.

In one aspect, the removing includes at least one of centrifuging and decanting.

In one aspect, the method further includes resuspending or dissolving the at least partially dehydrofluorinated fluoropolymer solid in a liquid, and forming a solid piezoelectric fluoropolymer material that exhibits a piezoelectric strain coefficient d₃₁ absolute value of greater than or equal to about 25 pm/V by removing at least a portion of the liquid from the resuspended or dissolved at least partially dehydrofluorinated fluoropolymer solid.

In one aspect, the forming includes performing a process selected from the group consisting of doctor blading, spin casting, printing, injection molding, slot die casting, micro gravure, extrusion, solution casting, spray coating, dip coating, and combinations thereof.

In one aspect, the method further includes forming a solid piezoelectric fluoropolymer material having β-phase and exhibiting a piezoelectric strain coefficient d₃₁ absolute value of greater than or equal to about 25 pm/V by three-dimensional printing, wherein the three-dimensional printing includes heating the at least partially dehydrofluorinated fluoropolymer solid to a temperature of greater than or equal to about 150° C. and directing the heated solid piezoelectric fluoropolymer material onto a target.

In one aspect, the piezoelectric fluoropolymer material includes greater than or equal to about 50 volume % β-phase.

In one aspect, the piezoelectric fluoropolymer material has a remnant polarization of greater than or equal to about 1 μC/cm².

In one aspect, the base is a volatile base and the dehydrofluorinating is performed in a liquid admixture including the fluoropolymer precursor, the volatile base, and a solvent, the fluoropolymer precursor being dissolved or suspended in the solvent, and the isolating includes, after the dehydrofluorinating, directly casting the liquid admixture into a predetermined shape and evaporating the solvent and the volatile base, wherein the at last partially dehydrofluorinated fluoropolymer solid forms as a solid piezoelectric fluoropolymer material having the predetermined shape, and having β-phase in an amount sufficient to exhibit a piezoelectric strain coefficient d₃₁ absolute value of greater than or equal to about 25 pm/V.

In one aspect, the base is an inorganic base.

In one aspect, the base is an organic base.

In one aspect, the dehydrofluorinating is performed until greater than or equal to about 2 vol. % to less than or equal to about 25 vol. % of the fluoropolymer precursor is dehydrofluorinated.

In various aspects, the current technology provides a method of making a piezoelectric component. The method includes heating an at least partially dehydrofluorinated fluoropolymer solid by applying heat at a temperature of greater than or equal to about 150° C. to create a flowable piezoelectric fluoropolymer, wherein the at least partially dehydrofluorinated fluoropolymer solid is isolated from a reaction between at least one of a poly(vinylidene fluoride) and a copolymer of vinylidene fluoride and a base; and forming the flowable piezoelectric fluoropolymer into a three-dimensional piezoelectric component having β-phase in an amount sufficient to exhibit a piezoelectric strain coefficient d₃₁ of greater than or equal to about 25 pm/V.

In one aspect, the at least partially dehydrofluorinated fluoropolymer solid includes greater than or equal to about 50 volume % β-phase.

In one aspect, the heating and the forming are performed during three-dimensional printing.

In one aspect, the forming includes injecting the flowable piezoelectric fluoropolymer into a mold.

In one aspect, the method includes incorporating the three-dimensional piezoelectric component as a component into a power source, a sensor, an actuator, a frequency standard, a motor, or a photovoltaic device.

In various aspects, the current technology provides a method of making a piezoelectric component. The method includes obtaining a at least partially dehydrofluorinated fluoropolymer solid isolated from a dehydrofluorination reaction between a base and at least one of a poly(vinylidene fluoride) and a copolymer of vinylidene fluoride; resuspending or dissolving the at least partially dehydrofluorinated fluoropolymer solid in a liquid to form a liquid including the at least partially dehydrofluorinated fluoropolymer; and forming the liquid including the at least partially dehydrofluorinated fluoropolymer into a solid piezoelectric component including a piezoelectric fluoropolymer having greater than or equal to about 50 volume % of β-phase and a remnant polarization of greater than or equal to about 1 μC/cm² by removing at least a portion of the liquid from the liquid comprising the at least partially dehydrofluorinated fluoropolymer.

In one aspect, the forming includes performing a process selected from the group consisting of doctor blading, spin casting, printing, injection molding, slot die casting, micro gravure, extrusion, solution casting, spray coating, dip coating, and combinations thereof.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A illustrates fully aligned dipoles (arrows indicating the dipole direction) in β-phase PVDF enabling higher piezoelectricity.

FIG. 1B illustrates the mechanism of PVDF dehydrofluorination through the formation of double bonds and the crosslinking of the polymer.

FIG. 2A shows FTIR spectra.

FIG. 2B illustrates XRD patterns of PVDF before and after different time of dehydrofluorination.

FIG. 3A illustrates polarization versus electrical fields plots (hysteresis loops) of PVDF films treated for 8 hours.

FIG. 3B illustrates polarization versus electrical fields plots (hysteresis loops) of PVDF films treated for 2-10 hours and untreated PVDF.

FIG. 3C illustrates their remnant polarization and coercive field values.

FIG. 4A shows strain versus electrical field plots (butterfly loop response).

FIG. 4B shows phase response of the β-phase PVDF.

FIG. 5A shows the crystalline structure of α-phase (TGTG′ conformation) PVDF. The arrows indicate the direction of molecular dipoles.

FIG. 5B shows the crystalline structure of β-phase (all-trans conformation) PVDF. The arrows indicate the direction of molecular dipoles.

FIG. 6A is a scheme of the dehydrofluorination reaction of PVDF.

FIG. 6B shows the dehydrofluorination rates of different amines in 7 wt. % PVDF/DMF solution with a concentration of agent: VDF=1:10.

FIG. 6C shows the X-ray photoelectron spectroscopy (XPS) spectra of untreated PVDF and dehydrofluorinated PVDF treated by EDA with varying reaction times.

FIG. 7A shows the Fourier transform infrared (FTIR) spectra of untreated PVDF films and EDA treated PVDF films with different reaction times.

FIG. 7B shows the calculated β-phase fraction of untreated PVDF films and EDA treated PVDF films with different reaction times.

FIG. 7C shows the β-phase fraction of dehydrofluorinated PVDF (% DHF=˜25%) treated by different dehydrofluorination agents.

FIG. 7D shows the X-ray diffraction (XRD) patterns of untreated PVDF films and EDA treated PVDF films with different reaction times.

FIG. 8A shows polarization versus electric field plots of dehydrofluorinated PVDF and untreated PVDF with different reaction times.

FIG. 8B shows remnant polarization and coercive field versus reaction time of dehydrofluorinated PVDF.

FIG. 8C illustrates the full ferroelectric hysteresis loop of dehydrofluorinated PVDF with a reaction time of 8 hours.

FIG. 9A show the blocking force under a unipolar electrical field of the dehydrofluorinated PVDF films.

FIG. 9B illustrates previously reported d₃₁ coefficients on PVDF and its copolymers compared to dehydrofluorinated PVDF.

FIG. 10A shows open circuit voltage and short circuit current generated by dehydrofluorinated PVDF devices.

FIG. 10B shows open circuit voltage and short circuit current generated by conventional uniaxial drawn PVDF devices.

FIG. 10C shows RMS voltage signal across different load resistances under 0.5% maximum strain excitation, measured from conventional uniaxial drawn PVDF and dehydrofluorinated PVDF.

FIG. 10D shows power density across different load resistances under 0.5% maximum strain excitation, measured from conventional uniaxial drawn PVDF and dehydrofluorinated PVDF.

FIG. 11A is an photograph of a dehydrofluorination reaction product.

FIG. 11B shows a Fourier-transform infrared spectroscopy (FTIR) spectrum of the reaction product shown in FIG. 11A.

FIG. 11C shows results of an x-ray diffraction scan of the reaction product shown in FIG. 11A.

FIG. 12A is an photograph of a dehydrofluorination reaction product.

FIG. 12B shows a Fourier-transform infrared spectroscopy (FTIR) spectrum of the reaction product shown in FIG. 12A.

FIG. 12C shows results of an x-ray diffraction scan of the reaction product shown in FIG. 12A.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges. As referred to herein, ranges are, unless specified otherwise, inclusive of endpoints and include disclosure of all distinct values and further divided ranges within the entire range. Thus, for example, a range of “from A to B” or “from about A to about B” is inclusive of A and B.

Example embodiments will now be described more fully with reference to the accompanying drawings

Electroactive polymers that can generate large mechanical strains in response to external electric fields have attracted a great deal of interest in recent years. One of the major goals of electroactive materials research is to develop biomimetic actuators that can generate large motions with high responding speed and precision and high strain energy density to produce large forces, to achieve the functions comparable to natural muscles. Many newly developed electroactive polymers have been reported to exhibit large strain at levels far above those from traditional inorganic piezoelectric materials. Some of these polymers even exhibit a much higher stain energy density than that of piezoelectric ceramics. Combining their renowned excellent properties including lightweight, ease of processing, and low cost, such polymers with stimuli-responsive abilities are used in many applications such as artificial muscles, smart skins, sensors, actuators, E-textiles, energy harvesters, MEMS devices and micro-fluid systems.

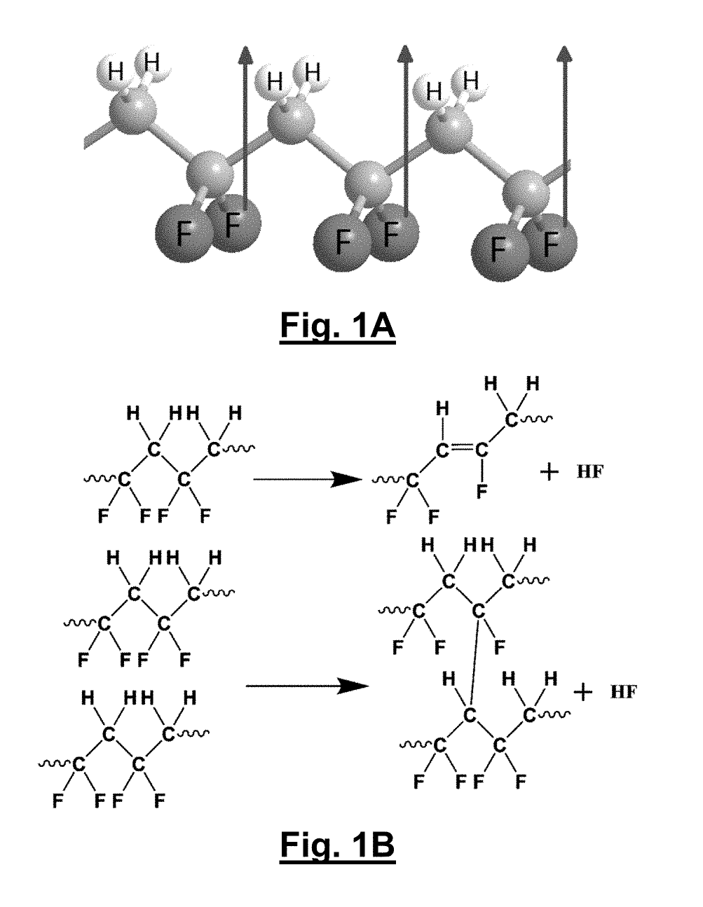

Among these polymers, piezoelectric polymers such as PVDF and its copolymers have been studied for a few decades for electromechanical device applications. As a piezoelectric material, PVDF is able to respond to external electric fields with high precision and speed, and generate relatively high stresses. However, the piezoelectric properties of PVDF are limited by its crystallization behavior because PVDF is a semi-crystalline polymer with multiple phases, including a paraelectric α-phase, a weak piezoelectric γ-phase, a strong piezoelectric β-phase, and the amorphous phase. Among these phases, the most desirable phase is the β-phase because it has an all-trans planar chain conformation where every repeat unit functions as an aligned dipole. This leads to the largest number of aligned permanent dipoles among all PVDF phases (see FIG. 1A) and results in better ferroelectric, piezoelectric, and pyroelectric properties.

Previously reported methods achieve high β-phase content in PVDF with an enhanced ferroelectricity through uni-axial stretching, controlling the evaporation rate and temperature, and heating processes such as annealing. However, the β-phase PVDF achieved from these methods, especially for the most common mechanical stretching method, are still limited to an insufficient β-phase amount and lack of thermo-stability. This limited β-phase content restricts PVDF from fully developing and utilizing its potential as a piezoelectric material. This shortcoming leads to a low strain level and strain energy density, which severely limits its prospect in actuator application.

The current technology provides a versatile method to prepare stable β-phase through dehydrofluorination of PVDF. The β-phase provides the highest piezoelectricity and ferroelectricity among all the phases of PVDF. A prepared β-phase PVDF is used to fabricate a thin film actuator, which exhibits high ferroelectricity (remnant polarization up to 6.31±0.15 ρC/cm²) and giant electromechanical coupling (piezoelectric strain coefficients d₃₃ having an absolute value of greater than or equal to about 20 pm/V and d₃₁ having an absolute value of greater than or equal to about 25 pm/V. A superior piezoelectric voltage coefficient (g33) of 0.41 Vm/N is calculated from such results and an exceptionally large piezoelectric strain (up to 3%) is observed from the PVDF actuator at room temperature under an oscillating electric field.

These properties of the dehydrofluorinated β-phase PVDF surpass those of more expensive PVDF copolymers currently used in piezoelectric actuators, indicating its great potential for application in the fabrication of high performance and low cost biomedical and mechanical actuators, and other piezoelectric devices.

The current technology provides a dehydrofluorination (DHF) process that induces defects into the PVDF polymer such that double bonds are formed and crosslinks may be formed. These defects have been found to preferentially induce crystallization in the β-phase without the need for drawing. The production of as cast PVDF films with high β-phase and piezoelectric coupling is now provided through a DHF process that produces greatly increased piezoelectricity relative to conventional methods.

The d₃₃ and d₃₁ values achieved through the current methods are also higher than any value reported in the literature for a piezoelectric polymer film and the g-coefficient is the highest of any material ever reported. The process allows 3D printing, injection molding, spin coating, and other forming and casting methods, of the polymer, all of which could never be applied for ferroelectric PVDF in the past.

In one embodiment, a method for synthesizing a piezoelectric material involves dissolving a starting fluoropolymer in a solvent with a weak base and then reacting the weak base and the starting fluoropolymer for a time sufficient to dehydrofluorinate the fluoropolymer and form a reaction mixture. Thereafter, the method involves recovering the dehydrofluorinated fluoropolymer as a solid from the reaction mixture. As a result of the method, the fluoropolymer in the reaction mixture has a higher content of β-phase than the starting fluoropolymer. In various embodiments, the starting fluoropolymer comprises poly (vinylidene fluoride) or a copolymer of vinylidene fluoride. In various embodiments, the weak base is a weak organic base, such as a weark primary, secondary or tertiary amine. For example, the weak organic base can be selected from C₁₋₆ monoamines and C₁₋₆ diamines. In the method, the solution contains a solvent as well as a fluoropolymer. In various embodiments, the solvent is selected from N-methyl pyrrolidone (NMP), dimethylsulfoxide (DMSO), N,N-dimethylformamide (DMF), methyl ethyl ketone (MEK), tetrahydrofuran (THF), and N,N-dimethylacetamide (DMAc). The vinylidene fluoride copolymer can be, in non-limiting fashion, a copolymer of vinylidene fluoride and trifluoroethylene (TrFE).

In another embodiment, a method for synthesizing a piezoelectric material involves contacting a fluoropolymer precursor with a base and then reacting the base and the fluoropolymer precursor for a time sufficient to at least partially dehydrofluorinate the fluoropolymer precursor. The fluoropolymer precursor comprises PVDF or a copolymer of vinylidene fluoride. Moreover, the fluoropolymer precursor can be dissolved in a solvent including the base or it can be suspended as a solid in a liquid admixture in which the base is dissolved. The base can be any inorganic or organic base. However, the time sufficient to at least partially dehydrofluorinated the fluoropolymer precursor depends on the strength and concentration of the base. For example, dehydrofluorinating with an organic base generally takes less time than dehydrofluorinating with a relatively weaker inorganic base. Thereafter, the method involves stopping the reacting by, for example, isolating a solid at least partially dehydrofluorinated fluoropolymer having β-phase and that exhibits melt flow processability at a temperature of greater than or equal to about 150° C. The solid at least partially dehydrofluorinated fluoropolymer is capable of forming a solid piezoelectric fluoropolymer material having β-phase in an amount sufficient to exhibit a piezoelectric strain coefficient d₃₁ absolute value of greater than or equal to about 25 pm/V.

In another embodiment, the starting fluoropolymer comprises a copolymer of vinylidene fluoride, trifluoroethylene, and either hexafluoropropylene (HFP) or chorotrifluoroethylene (CTFE). In various embodiments, the reaction is carried out at a temperature of greater than or equal to about 0° C. to a temperature less than the temperature at which the solvent boils, at a temperature of 0° to 50° C., or at approximately room temperature. After the reaction is complete, the dehydrofluorinated fluoropolymer can be recovered as a solid from the reaction mixture, or the reaction mixture can be used as a solution for casting films. in various embodiments, recovering the dehydrofluorinated as a solid from the reaction mixture comprises precipitating the solid fluoropolymer from the solution, or casting the reaction mixture and removing the solvent from the solution.

In another embodiment, a method for making a piezoelectric solid polymer material is provided that does not involve stretching the polymer material. The method includes the steps of reacting a starting polymer in a solution with a weak base such as an organic base to make a polymeric reaction product and recovering the polymeric reaction product from the solution. Identities of the starting polymer are given in the description of the embodiments above and further herein, and include poly(vinylidene fluoride) or a copolymer of vinylidene fluoride. The polymeric reaction product recovered from the solution is characterized by a piezoelectric strain coefficient d₃₃ that is higher than the piezoelectric strain coefficient of fluoropolymers obtained to date. In various embodiments, the piezoelectric strain coefficient d₃₃ (as an absolute value) is higher than 20 pm/V, higher than 25 pm/V, higher than 30 pm/V, or higher than 40 pm/V. Here, higher than 25 pm/V and similar terms mean that the strain coefficient is more negative than −25 pm/V and so on.

In some embodiments, the method further comprises drawing the polymeric reaction product.

In another embodiment, a method for making a stable β-phase poly (vinylidene fluoride) (PVDF), with or without stretching or drawing, involves reacting PVDF in a solvent with a weak base like an amine and recovering β-phase PVDF from the solution. Here and in other embodiments, the amine is selected, for example, from primary amines, secondary amines, tertiary amines, monoamines, and diamines.

Conveniently, the amine is chosen so as to be soluble in the reaction solvents so as to make clean up easy. In various embodiments, the amine is soluble or miscible in water. Reaction is carried out at a temperature below the boiling point of the solvent, at or at mild temperatures such as at 100° C. or less. In various embodiments, the temperature of reaction is 50° C. or less and is advantageously carried out at about room temperature or about 20° C. to 30° C. Conveniently, in various embodiments, the polymer is recovered from the solution by precipitation with water. Alternatively, the reaction mixture is ready for direct casting or dispensing as discussed in more detail below.

In one embodiment the current technology provides a method for synthesizing a piezoelectric material. The method comprises dehydrofluorinating a fluoropolymer precursor by incubating the fluoropolymer precursor in the presence of a base. The fluoropolymer precursor comprises poly(vinylidene fluoride) or a copolymer of vinylidene fluoride. The base can be any organic or inorganic base. The method also comprises isolating an at least partially dehydrofluorinated fluoropolymer solid having β-phase and that exhibits melt flow processability at a temperature of greater than or equal to about 150° C. The dehydrofluorinated fluoropolymer solid is also soluble in N-methyl pyrrolidone (NMP), dimethylsulfoxide (DMSO), N,N-dimethylformamide (DMF), methyl ethyl ketone (MEK), tetrahydrofuran (THF), N,N-dimethylacetamide (DMAc), and combinations thereof. The dehydrofluorinating is performed until a product is generated that, when in a solid form, has melt flow processability and piezoelectric properties. In some embodiments, the dehydrofluorinating is performed until greater than or equal to about 2 vol. % to less than or equal to about 25 vol. %, greater than or equal to about 3 vol. % to less than or equal to about 20 vol. %, greater than or equal to about 4 vol. % to less than or equal to about 15 vol. %, or greater than or equal to about 5 vol. % to less than or equal to about 10 vol. % of the fluoropolymer precursor is dehydrofluorinated. In various embodiments, dehydrofluorinating is performed until about 3 vol. %, about 4 vol. %, about 5 vol. %, about 6 vol. %, about 7 vol. %, about 8 vol. %, about 9 vol. %, about 10 vol. %, about 12 vol. %, about 14 vol. %, about 16 vol. %, about 18 vol. %, about 20 vol. %, or about 25 vol. % of the fluoropolymer precursor is dehydrofluorinated. Accordingly, the dehydrofluorinating time depends on the strength and concentration of the base. The at least partially dehydrofluorinated fluoropolymer solid is capable of forming a solid piezoelectric fluoropolymer material having β-phase in an amount sufficient to exhibit a piezoelectric strain coefficient d₃₁ absolute value of greater than or equal to about 25 pm/V.

In some embodiments, during the dehydrofluorinating, fluoropolymer precursor and the base are combined with, and dissolved in, a solvent selected from the group consisting of N-methyl pyrrolidone (NMP), dimethylsulfoxide (DMSO), N,N-dimethylformamide (DMF), methyl ethyl ketone (MEK), tetrahydrofuran (THF), N,N-dimethylacetamide (DMAc), and combinations thereof. Here, the dehydrofluorinating forms an at least partially dehydrofluorinated reaction product present in the solvent, and the isolating further comprises precipitating the at least partially dehydrofluorinated reaction product from the liquid admixture and recrystallizing the at least partially dehydrofluorinated reaction product to form the at least partially dehydrofluorinated fluoropolymer solid.

In other embodiments, during the dehydrofluorinating, the fluoropolymer precursor is a solid fluoropolymer precursor that is suspended in a liquid admixture comprising the base. Here, the dehydrofluorinating forms the at least partially dehydrofluorinated fluoropolymer solid from the solid fluoropolymer precursor, and the isolating further comprises removing the solid at least partially dehydrofluorinated fluoropolymer from the liquid admixture. The removing can be performed by any method known in the art, such as, for example, by at least one of centrifuging, and decanting.

The isolating the at least partially dehydrofluorinated fluoropolymer solid neutralizes the dehydrofluorination reaction by separating the fluoropolymer precursor from the base. However, it is understood that in some embodiments where the base is an inorganic base, the dehydrofluorination reaction can be stopped or slowed by neutralizing the inorganic base by adding an acid. The inorganic base reacts with acids to generate a salt that is not reactive. Alternatively, in some embodiments where the base is an organic base, the dehydrofluorination reaction can be stopped or slowed by converting the organic base into another organic molecule that is not reactive with the fluoropolymer precursor. As non-limiting examples, some inorganic bases react with acids to generate ammonium salts that do not react with the fluoropolymer precursor or the inorganic base can be converted into an alcohol that does not react with the fluoropolymer precursor.

As discussed above, the at least partially dehydrofluorinated fluoropolymer solid is capable of forming a solid piezoelectric fluoropolymer material having β-phase in an amount sufficient to exhibit a piezoelectric strain coefficient d₃₁ absolute value of greater than or equal to about 25 pm/V. Accordingly, in various embodiments, the method further comprises forming a solid piezoelectric fluoropolymer material that exhibits a piezoelectric strain coefficient d₃₁ absolute value of greater than or equal to about 25 pm/V from the at least partially dehydrofluorinated fluoropolymer solid. In some aspects, the forming comprises resuspending or dissolving the at least partially dehydrofluorinated fluoropolymer solid in a liquid and forming the solid piezoelectric fluoropolymer material that exhibits a piezoelectric strain coefficient d₃₁ absolute value of greater than or equal to about 25 pm/V by removing at least a portion of the liquid from the resuspended or dissolved at least partially dehydrofluorinated fluoropolymer solid. The removing is performed by any method known in the art, such as, for example, by evaporating at least a portion of the liquid, with or without heating in an oven and/or under vacuum, wherein the term “at least a portion of the liquid” refers to greater than or equal to about 50 vol. % of the liquid, greater than or equal to about 60 vol. % of the liquid, greater than or equal to about 70 vol. % of the liquid, greater than or equal to about 80 vol. % of the liquid, greater than or equal to about 90 vol. % of the liquid, greater than or equal to about 95 vol. % of the liquid, or greater than or equal to about 99 vol. % of the liquid, or from greater than or equal to about 60 vol. % to less than or equal to about 100 vol. % of the liquid. As the liquid is removed, the solid piezoelectric fluoropolymer material forms. The forming is performed by any process known in the art, including a process selected from the group consisting of doctor blading, spin casting, printing, injection molding, slot die casting, micro gravure, extrusion, solution casting, spray coating, dip coating, and combinations thereof.

In other aspects, the forming comprises three-dimensional printing, which comprises heating the at least partially dehydrofluorinated fluoropolymer solid to a temperature at which the at least partially dehydrofluorinated fluoropolymer solid becomes melt processable and directing the heated solid piezoelectric fluoropolymer material onto a target, such as a substrate or a previously printed element. As used herein “melt processable” or “melt processability” refers to the ability or behavior of the at least partially dehydrofluorinated fluoropolymer solid to soften and adapt a viscosity, i.e., a melt viscosity, such that the heated at least partially dehydrofluorinated fluoropolymer has the ability to flow. The viscosity is, for example, greater than or equal to about 20 kP to less than or equal to about 150 kP, or greater than or equal to about 50 kP to less than or equal to about 100 kP, such a viscosity of about 20 kP, about 30 kP, about 40 kP, about 50 kP, about 60 kP, about 70 kP, about 80 kP, about 90 kP, about 100 kP, about 110 kP, about 120 kP, about 130 kP, about 140 kP, or about 150 kP. The at least partially dehydrofluorinated fluoropolymer solid exhibits melt flow behavior at a temperature of greater than or equal to about 150° C. to less than or equal to about 200° C., greater than or equal to about 155° C. to less than or equal to about 190° C., or greater than or equal to about 160° C. to less than or equal to about 175° C.

In some embodiments, the base is a volatile base and the dehydrofluorinating is performed in a liquid admixture comprising the fluoropolymer precursor, the volatile base, and a solvent, the fluoropolymer precursor being dissolved or suspended in the solvent, and the isolating comprises, after the dehydrofluorinating, directly casting the liquid admixture into a predetermined shape and evaporating the solvent and the volatile base, wherein the at last partially dehydrofluorinated fluoropolymer solid forms as a solid piezoelectric fluoropolymer material having the predetermined shape, and having β-phase in an amount sufficient to exhibit a piezoelectric strain coefficient d₃₁ absolute value of greater than or equal to about 25 pm/V. Non-limiting examples of volatile bases include ammonia, hydrazine, methylamine, ethylamine, diethylamine, triethylamine, isobutylamine, N,N-diisopropylethylamine, morpholine, piperazine, ethylenediamine, 1,4-diazabicyclo[2.2.2]octane, and combinations thereof. The predetermined shape can be three-dimensionally casted by, for example, three-dimensional printing, or the predetermined shape can be thin film casted by any method described herein suitable for casting thin films.

The piezoelectric fluoropolymer material comprises greater than or equal to about 15 vol. % β-phase, greater than or equal to about 20 vol. % β-phase, greater than or equal to about 30 vol. % β-phase, greater than or equal to about 40 vol. % β-phase, or greater than or equal to about 50 vol. % β-phase. The piezo electric fluoropolymer also has ferroelectric activity, such as a remnant polarization of greater than or equal to about 1 μC/cm², greater than or equal to about 2.5 μC/cm², or greater than or equal to about 5 μC/cm², such as a remnant polarization of about 1 μC/cm², about 1.5 μC/cm², about 2 μC/cm², about 2.5 μC/cm², about 3 μC/cm², about 3.5 μC/cm², about 4 μC/cm², about 4.5 μC/cm², about 5 μC/cm², about 5.5 μC/cm², about 6 μC/cm², about 6.5 μC/cm², about 7 μC/cm², about 7.5 μC/cm², about 8 μC/cm², about 8.5 μC/cm², about 9 μC/cm², about 9.5 μC/cm², about 10 μC/cm², or higher.

Additionally, the piezoelectric fluoropolymer material can be stretched or drawn to yet further improve piezoelectric coupling.

In another embodiment, the current technology provides a method of making a piezoelectric component. The method comprises heating an at least partially dehydrofluorinated fluoropolymer solid by applying heat at a temperature of greater than or equal to about 150° C., to create a flowable piezoelectric fluoropolymer, wherein the at least partially dehydrofluorinated fluoropolymer solid is isolated from a reaction between at least one of a poly(vinylidene fluoride) and a copolymer of vinylidene fluoride and a base. The temperature of greater than or equal to about 150° C. can be, for example, greater than or equal to about 150° C. to less than or equal to about 200° C., greater than or equal to about 155° C. to less than or equal to about 190° C., or greater than or equal to about 160° C. to less than or equal to about 175° C. The reaction results in the at least one of the poly(vinylidene fluoride) and the copolymer of vinylidene fluoride to become dehydrofluorinated to become greater than or equal to about 2 vol. % to less than or equal to about 25 vol. %, greater than or equal to about 3 vol. % to less than or equal to about 20 vol. %, greater than or equal to about 4 vol. % to less than or equal to about 15 vol. %, or greater than or equal to about 5 vol. % to less than or equal to about 10 vol. % dehydrofluorinated. In various embodiments, at least one of the poly(vinylidene fluoride) and the copolymer of vinylidene fluoride become about 3 vol. %, about 4 vol. %, about 5 vol. %, about 6 vol. %, about 7 vol. %, about 8 vol. %, about 9 vol. %, about 10 vol. %, about 12 vol. %, about 14 vol. %, about 16 vol. %, about 18 vol. %, about 20 vol. %, or about 25 vol. % dehydrofluorinated. The at least partially dehydrofluorinated fluoropolymer solid comprises β-phase in an amount as described above.

The method further comprises forming the flowable piezoelectric fluoropolymer into a three-dimensional piezoelectric component having β-phase in an amount sufficient to exhibit a piezoelectric strain coefficient as described above.

In one aspect, the heating and the forming are performed during three-dimensional printing. In another aspect, the forming comprises injecting the flowable piezoelectric fluoropolymer into a mold.

The method can also include incorporating the three-dimensional piezoelectric component as a component into a power source, a sensor, a microphone, an actuator, a frequency standard, a motor, or a photovoltaic device.

In yet another embodiment, the current technology provides a method of making a piezoelectric component. The method comprises obtaining an at least partially dehydrofluorinated fluoropolymer solid isolated from a dehydrofluorination reaction between a base and at least one of a poly(vinylidene fluoride) and a copolymer of vinylidene fluoride, as described above. The method then comprises resuspending or dissolving the at least partially dehydrofluorinated fluoropolymer solid in a liquid to form a liquid comprising the at least partially dehydrofluorinated fluoropolymer, and forming the liquid comprising the at least partially dehydrofluorinated fluoropolymer into a solid piezoelectric component comprising a piezoelectric fluoropolymer having greater than or equal to about 50 volume % of β-phase and a remnant polarization of greater than or equal to about 1 μC/cm² by removing at least a portion of the liquid from the liquid comprising the at least partially dehydrofluorinated fluoropolymer. The forming comprises performing a process selected from the group consisting of doctor blading, spin casting, printing, injection molding, slot die casting, micro gravure, extrusion, solution casting, spray coating, dip coating, and combinations thereof.

The above embodiments and others described herein are characterized in various ways by the choice of fluoropolymer used, by the identity of the base, by the reaction conditions of time and temperature, by the solvent used, by the ferroelectric values of the dehydrofluorinated polymers (for example d₃₃ or d₃₁) obtained, by the conditions of optional annealing steps, and other ways. It is to be understood that the various embodiments described herein can be provided with various values of all of the above parameters to describe other embodiments not otherwise explicitly provided. A description of the various parameters of the invention follows.

Fluoropolymer.

The fluoropolymer is selected from known piezoelectric fluoropolymers of the prior art. In one aspect, the fluoropolymer is a homopolymer of vinylidene fluoride or poly (vinylidene fluoride) (abbreviated as “PVDF”). In another embodiment, the fluoropolymer is selected as a copolymer containing vinylidene fluoride. This is referred to as a copolymer of VDF. Of particular interest is a copolymer of vinylidene fluoride and trifluoroethylene (TrFE). Among those of interest are copolymers of VDF and TrFE containing 20 mol %, 25 mol %, or about 30 mol % TrFE.

Terpolymers containing VDF are also useful. Examples include terpolymers of VDF and TrFE, plus additionally hexafluoropropylene (HFP). Another non-limiting example is a terpolymer containing VDF, TrFE, and chlorotrifluoroethylene (CTFE).

Other monomers can be copolymerized with VDF to make other piezoelectric polymers. The piezoelectric materials are characterized in that there is a so-called β-phase that has suitable piezoelectric properties. Until now, the β-phase of these fluoropolymers could only be reached by stretching the polymers in such a way as to obtain piezoelectric films. The fluoropolymers treated according to the current teachings, however, are not limited to the physical form of thin films and can be obtained without orienting or stretching the polymer films after the dehydrofluorination reaction.

Bases.

The base used in dehydrofluorination reaction according the current technology is not limited. The base can be any inorganic or organic base. However, the rate of reaction is dependent on the properties of the base used. For example, bases having a low pKa of less than about 10, also referred to as “weak bases,” provide a slower dehydrofluorination rate relative to bases having a high pKa of greater than or equal to about 10, also referred to as “strong bases.” In general, a strong base undergoes a higher degree of ionization in solution that a weak base. Put another way, a first base that has a higher pKa relative to a second base undergoes a higher degree of ionization in solution than the second base, and the first base is strong relative to the second base, and the second base is weak relative to the first base. Reaction rates can be controlled by stopping or slowing the dehydrofluorination reaction after a time dependent on the strength of the base, by adjusting a concentration of the base, and/or by controlling the temperature, wherein lower temperatures provide for slower reaction rates than relatively higher temperatures. Stopping or slowing the reaction in a liquid admixture including a fluoropolymer precursor and a base can include precipitating a reaction product from the liquid admixture, neutralizing the base with an acid, converting the base into another non-basic compound, or evaporating the base when the base is volatile. Notably, a reaction can also be controlled by neutralizing or reducing the basicity of the solution as the reaction progresses.

In some embodiments, the base is an organic base. The most common organic bases useful in the current teachings, may be “weak bases” as defined above. In various embodiments, the amines are preferably primary, secondary, or tertiary amines and can be chosen from monoamines and diamines. Nonetheless, it is understood that the organic base is not limited to primary and secondary amines, and may alternatively be, for example, a tertiary amine, aniline, pyridine, imidazole, hydrazine, or ammonia. Other exemplary organic bases include ethylene diamine, methylamine, trimethylamine, dimethylamine, diethylamine, trimethylamine (TEA), 1,4-diazabicyclo[2.2.2]octane (DABCO), and 1,8-Diazabicyclo[5.4.0]undec-7-ene (DBU). In various embodiments, the organic amines are selected from those in the C₁₋₆ range. In various embodiments, the amines are water soluble or even miscible in water.

In other embodiments, the base in an inorganic base. Non-limiting examples of inorganic bases include LiOH, NaOH, KOH, RbOH, CsOH, Ca(OH)₂, Sr(OH)₂, and Ba(OH)₂.

Reaction Conditions.

The dehydrofluorination reaction is carried out by contacting the fluoropolymer precursor and the base at suitable concentrations for a suitable time and at a temperature sufficient to prepare a treated fluoropolymer that has an elevated content of β-phase and which has suitable physical properties. Advantageously, the reaction can be carried out at ambient or close to ambient conditions, such as at temperatures below 100° C. In various embodiments, the reaction is advantageously carried out at about room temperature, which can be taken as ranges of 10° to 50° C. or a range of 20° to 40° C. In other embodiments, the reaction is carried out at a temperature of 20° C. to 30° C., or at about 25° C.

Although not normally required, the reaction can even be carried out at temperatures below room temperature, such as in an ice bath at a temperature of approximately 0° C.

The time of reaction is taken as any time sufficient to increase the level of beta phase in the fluoropolymer. Specific examples of suitable times are given in the Examples and figures below. In general, reaction is carried out for an hour, a few hours, or up to about eight to twelve hours, depending on the base. Suitable reaction conditions are described in the working example.

In some embodiments, the dehydrofluorinating is performed until greater than or equal to about 2 vol. % to less than or equal to about 25 vol. %, greater than or equal to about 3 vol. % to less than or equal to about 20 vol. %, greater than or equal to about 4 vol. % to less than or equal to about 15 vol. %, or greater than or equal to about 5 vol. % to less than or equal to about 10 vol. % of the fluoropolymer precursor is dehydrofluorinated. In various embodiments, dehydrofluorinating is performed until about 3 vol. %, about 4 vol. %, about 5 vol. %, about 6 vol. %, about 7 vol. %, about 8 vol. %, about 9 vol. %, about 10 vol. %, about 12 vol. %, about 14 vol. %, about 16 vol. %, about 18 vol. %, about 20 vol. %, or about 25 vol. % of the fluoropolymer precursor is dehydrofluorinated.

Solvents and Liquids.

In some embodiments, a suitable solvent is one that will dissolve the fluoropolymer and the weak base. Non-limiting examples include N-methylpyrrolidone (NMP), dimethyl sulfoxide (DMSO), dimethylformamide (DMF), dimethylacetamide (DMAc), tetrahydrofuran (THF), and acetone. A suitable solvent is further one that will precipitate the fluoropolymer from the solution by addition of a non-solvent such as water.

In other embodiments, the fluoropolymer precursor is reacted with a base as a solid or solid powder. In these embodiments, the solid fluoropolymer precursor is added to a non-solvent or a latent solvent, i.e., a liquid that dissolves the base, but does not dissolve the solid fluoropolymer precursor. Put another way, the solid fluoropolymer precursor is added to a liquid admixture comprising the base to form a suspension.

Ferroelectric Values of the Dehydro Fluorinated Polymers.

The fluoropolymers made by the methods disclosed herein have high piezoelectric strain coefficients, d₃₃ and d₃₁, compared to fluoropolymers in the prior art. The units of the piezoelectric strain coefficient d₃₃ are given equivalently as 10-12 C/N (coulombs of surface charge per Newton of surface strain) or as pm/V, or picometers per volt. Values of the coefficient are given as absolute values in units of pm/V. Thus, in various embodiments, polymers prepared by the disclosed methods have a coefficient d₃₃ (absolute value) greater than or equal to about 20 pm/V, greater than or equal to about 30 pm/V, greater than or equal to about 35 pm/V, greater than or equal to about 40 pm/V, greater than or equal to about 45 pm/V, greater than or equal to about 50 pm/V, or greater than or equal to about 60 pm/V, such as, for example, a d₃₃ (absolute value) of greater than or equal to about 20 pm/V to less than or equal to about 70 pm/V, and a coefficient d₃₁ (absolute value) of greater than or equal to about 15 pm/V, greater than or equal to about 20 pm/V, greater than or equal to about 25 pm/V, greater than or equal to about 35 pm/V, greater than or equal to about 40 pm/V, or greater than or equal to about 45 pm/V, such as, for example, a d₃₁ of greater than or equal to about 15 pm/V to less than or equal to about 50 pm/V. If by convention the coefficient d₃₃ or d₃₁ takes on a negative value, these values are understood as the absolute value of a negative d₃₃ or d₃₁. It is also possible to characterize them as more negative than −30 pm/V, more negative than −35 pm/V, and so on. Any of those values can be the lower range of coefficients d₃₃ or d₃₁. In various embodiments, the coefficient d₃₃ is less than or equal to about 100 pm/V, less than or equal to about 90 pm/V, or less than or equal to about 80 pm/V, with a similar proviso for negative values and the coefficient d₃₁ is less than or equal to about 70 pm/V, less than or equal to about 60 pm/V, less than or equal to about 50 pm/V with a similar proviso for negative values. Any of these values can be the upper range of values obtained for strain coefficient d₃₃ or d₃₁. In preferred embodiments, the coefficients d₃₃ and/or d₃₁ obtained for the fluoropolymers is higher (or equivalently more negative) than those known in the prior art and which are made by different methods.

Optional Annealing.

Optionally, annealing can be carried out. The annealing process is used to increase crystallinity of films or to increase the smoothness of samples to be used for doctor blading and spin coating. Other processing methods, for example, extrusion and 3D printing, do not require the annealing step.

In a typical annealing process, a prepared thin film is placed in an oven and heated up to 200° C. Once it reaches 200° C., the temperature of the oven is slowly decreased to room temperature over a suitably long time period, such as five hours, for example, with a rate of about 0.5° C. per minute.

Embodiments of the present technology are further illustrated through the following non-limiting examples.

### EXAMPLES

### Example 1

The present teachings show how a high quality β-phase PVDF is prepared through a controllable dehydrofluorination method. Although the invention is not limited to a theory or a mechanism of action, it is believed that a dehydrofluorination reaction occurs when PVDF is under either a basic or high temperature condition. Through the dehydrofluorination reaction, PVDF is degraded by losing hydrogen fluoride (HF) and either carbon-carbon double bonds form in the molecular backbone or single bonds form crosslinking the two polymer chains, as shown in FIG. 1B. These changes in structure in turn influence the crystallization behavior of PVDF and therefore, influence the electrical properties by changing the dipoles arrangement. The β-phase content in the slightly dehydrofluorinated PVDF increases because the stiff and planar double bonds in the polymer backbones induce a more planar conformation (β-phase) of PVDF. However, in the case of over-dehydrofluorinated PVDF, an increase of undesirable crosslinks and excess degradation will occur, interrupting the crystallinity of PVDF and reducing the electrical properties. Thus, by controlling the extent of dehydrofluorination, a stable β-phase PVDF with unprecedented electrical properties can be obtained.

Tests of thin films show that this method leads to the following properties, all of which are large for a polymeric material: Remnant polarization of 6.31 μC/cm², piezoelectric strain coefficient (d₃₃) of −71.84 pm/V, and piezoelectric strain of 3%.

In previous research, strong inorganic bases, such as sodium hydroxide and potassium hydroxide, were used to induce fast dehydrofluorination, which caused over-reaction and reduced the electric properties. The action of strong bases can be lessened or controlled by carrying out the reaction for short times or by reducing the temperature of reaction, and the teachings include reacting with strong base such as NaOH or KOH at reduced temperatures, even at room temperature or lower, such as 0° C. (ice bath). In other embodiments, instead of using a strong base, the present teachings provide for employing a weak organic base for better control. In a non-limiting embodiment, a weak base such as ethylene diamine (EDA) is added to a PVDF/N,N′-dimethylformamide (DMF) solution to slowly induce the dehydrofluorination of PVDF. The extent of dehydrofluorination is controlled by the reaction time and temperature. After treating with the weak organic base, smooth dehydrofluorinated PVDF thin films can be readily made by doctor blading, spin coating, 3D printing or injection molding methods, followed by a high temperature annealing process to increase crystallinity.

From these PVDF thin films, experimental evidence shows that the β-phase is increased and becomes the dominant phase through the dehydrofluorination process. Furthermore, we present experimental results showing that these dehydrofluorinated PVDF thin films achieve high ferroelectricity and giant piezoelectric properties. A piezoelectric strain coefficient d₃₃ larger than any previously reported PVDF is achieved and a large piezoelectric strain up to 3% is observed. These distinct features of this dehydrofluorinated PVDF promise their broad applications in transducers, actuators and energy harvesting devices.

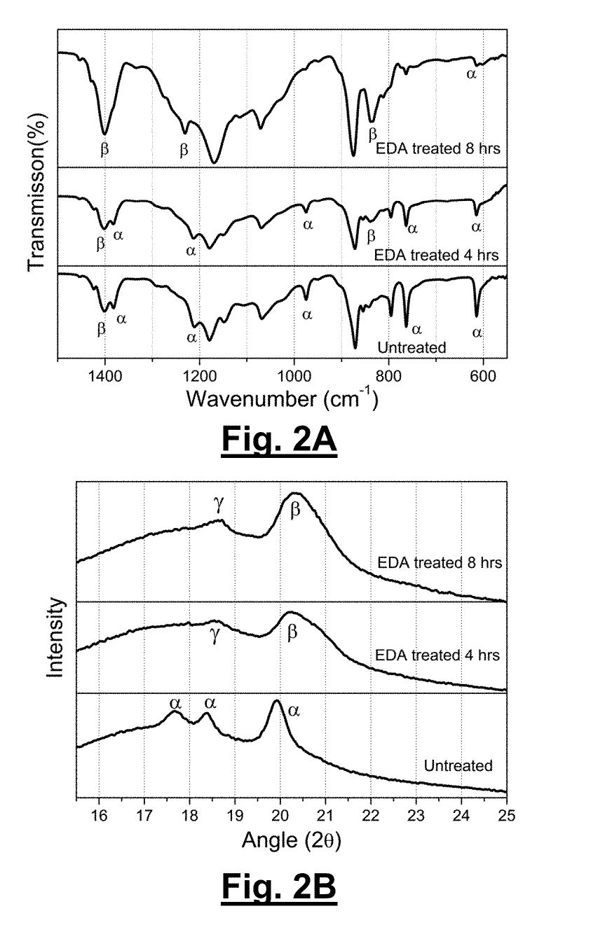

To experimentally prove formation of the β-phase PVDF through dehydrofluorination, Fourier-transform infrared spectroscopy (FTIR) and X-ray diffraction (XRD) measurements are performed. FTIR spectra of untreated and dehydrofluorinated PVDF of different reaction times are shown in FIG. 2A. This shows that the paraelectric α-phase is dominant in the untreated PVDF film, but coexists with a very small amount of β-phase and γ-phase. However, dehydrofluorination slowly induces the β-phase and thus, induces ferroelectric properties to the treated PVDF.

As shown in FIG. 2A, after 4 hours of dehydrofluorination, the composition of PVDF becomes a mixture of α-phase and β-phase where the characteristic bands of α-phase become weaker and the bands of β-phase become stronger. After 8 hours of dehydrofluorination, the PVDF is dominated by the β-phase, with only a very small amount of the α-phase and the γ-phase remaining. This phase identification is confirmed by XRD measurements on the same thin film samples (FIG. 2B). The peaks at 17.6° and 19.9°, which can be ascribed as the α-phase, are dominating in the pattern of untreated PVDF samples but disappear in the XRD patterns of the dehydrofluorinated PVDF samples. It is also observed that the intensities of the peak at 20.3°, representing the β-phase, and the peak at 18.6°, representing both β-phase and γ-phase because of their similar crystal structure, are both increasing along with increasing dehydrofluorination time.

Such results indicate that, through dehydrofluorination, the β-phase appears and increases as reaction time increases, accompanied with a decrease of the α-phase, proving that the β-phase is formed under the influences of dehydrofluorination. In the case of prolonged reaction time, the β-phase composition remained dominant in the XRD patterns and the FTIR spectra, indicating that extra reaction time (more than 8 hours) is unnecessary.

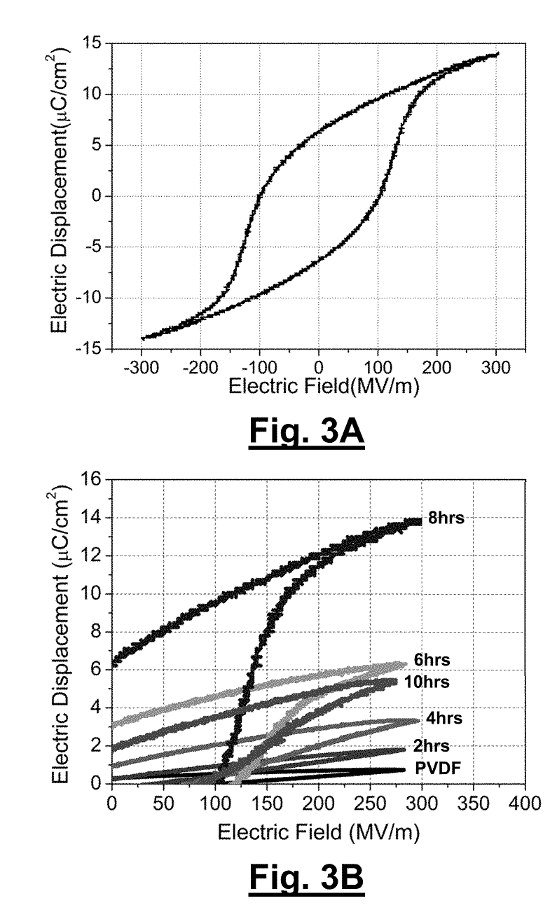

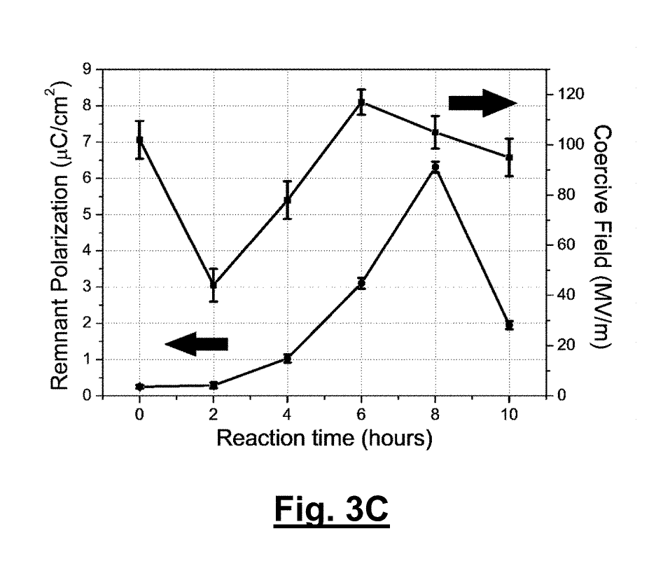

In order to measure the ferroelectric properties of dehydrofluorinated PVDF, a Sawyer-Tower circuit is used. The polarization versus electrical field relationship is obtained by applying a sinusoidal voltage signal with a frequency of 100 Hz and a maximum amplitude of 300 MV/m onto the circuit. As shown in FIG. 3A, dehydrofluorinated PVDF sample with 8 hours reaction time exhibits a typical ferroelectric polarization hysteresis loop with a maximum remnant polarization of 6.31±0.15 μC/cm² (polarization at field E=0) and a coercive field of 105±5 MV/m (field at polarization P=0). The ferroelectricity obtained from the present invention's PVDF thin films surpassed that of many previously reported PVDF and is even comparable to that of the ferroelectric enhanced PVDF trifluoroethylene copolymers, or P(VDF-TrFE).

FIG. 3B shows the hysteresis loops of pristine PVDF and dehydrofluorinated PVDF films under a sinusoidal electric field with a maximum amplitude of 300 MV/m. Their remnant polarizations and coercive fields are shown as well in FIG. 3C. This behavior demonstrates that the remnant polarizations of EDA treated PVDF films can be in the range of 0.29±0.08 to 6.31±0.15 μC/cm², increasing significantly with longer treatment time. Meanwhile, the remnant polarization of the untreated α-phase PVDF film is only 0.25±0.05 μC/cm² and does not display any ferroelectric properties.

As mentioned above, the β-phase has better ferroelectric performance than the α-phase and the γ-phase. Larger ferroelectric domains exist in the thin film because the planar conformation of the β-phase allows the formation of more aligned permanent dipoles in the same direction. This increasing remnant polarization also indicates that the percentage of the β-phase rises as treatment time increases. However, it should also be noted that ferroelectricity decreased significantly in the PVDF film when treated with EDA for longer than 8 hours. For instance, the remnant polarization in the PVDF sample treated for 10 hours is measured to only be 1.95±0.11 μC/cm². This decrease is caused by the increase in crosslinks formed by the over-reacted dehydrofluorination since a high degree of crosslinking will lead to less crystallinity, thus decreasing the dipole domain size.

FIG. 3C shows that the coercive field decreases below 50 MV/m when PVDF is treated with EDA for a short time, such as 2 hours (coercive field is 44±7 MV/m). However, the coercive field increases with an increasing treatment time and eventually increases to around 100 MV/m. The reason why the coercivity in the lightly dehydrofluorinated PVDF decreases is speculated to be because the coexistence of different phases (observed in the FTIR and the XRD results) induces more grain boundaries. This measurement reveals the high ferroelectric properties in the dehydrofluorinated PVDF. Furthermore, this indicates the optimal reaction time of dehydrofluorination in inducing the β-phase in PVDF, providing that EDA treated PVDF samples with a reaction time of 8 hours has the highest content of effective β-phase thus has the highest ferroelectricity.

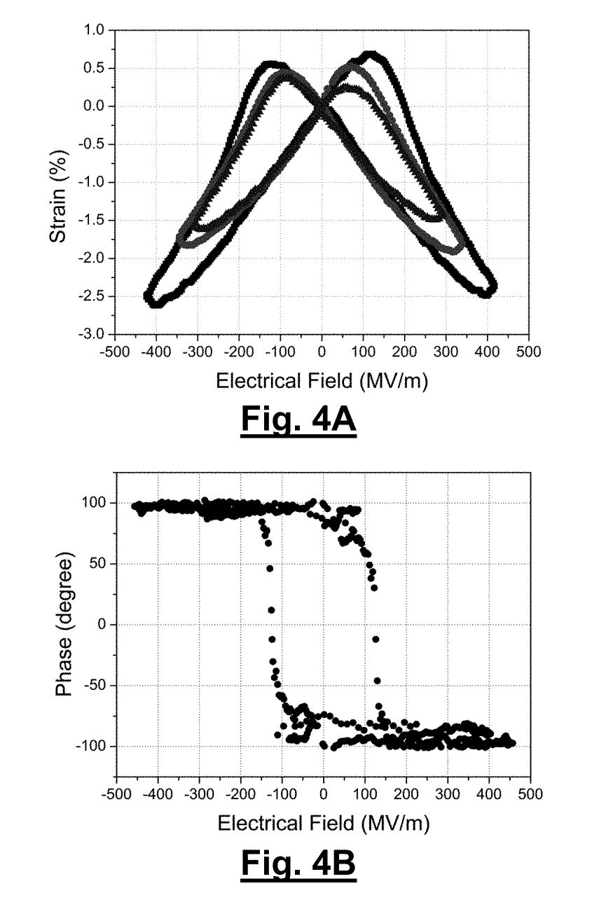

A refined piezoelectric force microscopy (PFM) testing setup is performed to characterize the piezoelectric properties of the β-phase PVDF as an actuator material. Dehydrofluorinated PVDF is spin-coated onto a piece of gold coated silicon wafer, which serves as the bottom electrode. A thin film actuator is thus fabricated with a PVDF thickness of ˜350 nm, where the thickness of the coated film is measured using a non-contact mode topography scan at a low scan speed. The PFM testing is performed using a Pt-coat conductive tip (40 N/m in force constant) on the film surface with an 1200 nN applied normal force, serving as the top PFM electrode. An AC voltage (1 Hz triangle wave) in range of 0.5 V˜1.5 V is amplified by 200 times and applied through the top PFM electrode to measure piezoelectric properties under the high electrical fields. An AC signal frequency (17 kHz) on a lock-in amplifier is used to reduce low-frequency noise and drift near the cantilever resonance (325 kHz). The plots of strain versus bipolar electrical field from the β-phase PVDF thin film are shown in FIG. 4A and display a typical butterfly loop response, which is attributed to the nature of domain motion and piezoelectric properties of PVDF.

The hysteresis loop of phase versus electrical field from the β-phase PVDF is presented in FIG. 4B and shows the phase changing from ˜90° to ˜−90° under the bipolar excitation voltage, which can be interpreted as a result of switching the polarization direction of the thin film with the coercive field matching both the phase and strain loops. A large strain of up to 3% from the β-phase PVDF is observed from the butterfly loop shown in FIG. 4A and is comparable to irradiated PVDF copolymers with trifluoroethylene or irradiated P(VDF-TrFE), which are widely reported as high performance polymer actuators. A giant piezoelectric strain coefficient d₃₃ of up to −71.84±1.73 pm/V is calculated from FIG. 4A. This giant d₃₃ value corresponds to the large aligned dipole domains induced by large β-phase content in this dehydrofluorinated PVDF that has been proved through the characterizations above. Remarkably, this d₃₃ value is larger than any other reported d₃₃ values for PVDF and PVDF copolymers devices. Therefore, the present invention is an excellent candidate for energy harvesting, sensing and actuating devices because of its superior properties over existing PVDF based polymers.

A high strain level is not convincing enough for evaluating an actuator material, especially for soft polymers because the Maxwell stress effect generated by the Coulomb force between accumulated charges may also induce a high strain to the soft material. Therefore, other parameters including strain energy density are also important in evaluating actuator materials. Here, we evaluate the strain energy density of dehydrofluorinated PVDF in terms of volumetric energy density, which is proportional to Eε²/2, and gravimetric energy density, which is proportional to Eε²/2ρ, where E is the Young's modulus, ε is the generated strain level and ρ is the density of the material.

To calculate the strain energy density, a Young's modulus (E) of 2.51±0.05 GPa is used as measured from the dehydrofluorinated PVDF through a tensile measurement following the ASTM D882 standard, and a strain level (ε) of 3% is used as obtained from the PFM measurement discussed previously. The results are compared with several previously reported actuator materials in Table 1 below, including a traditional piezoceramic material lead-zinc titanate (PZT), a piezoelectric single crystal lead-zinc-niobate/lead titanate (PZN-PT), a silicone dielectric elastomer, and a P(VDF-TrFE) electrostrictor.

TABLE 1
Young's modulus, strain and strain energy density (volumetric and
gravimetric) of dehydrofluorinated PVDF and other materials.

| Material | E (GPa) | Strain (ε) | | Eε²/2ρ (J/kg) |
|---|---|---|---|---|
| | | | Eε²/2 (J/cm³) | |
| Piezoceramic (PZT) | 7.5 | 0.15% | 0.008 | 1.1 |
| Single crystal PZN-PT | 7.7 | 1.7% | 1.11 | 146 |
| Silicone dielectric | 0.01 | 25% | 0.31 | 135 |
| elastomer | | | | |
| P (VDF-TrFE) | 0.38 | 4% | 0.3 | 160 |
| electrostrictor | | | | |
| Dehydrofluorinated | 2.5 | 3% | 1.13 | 632 |
| PVDF actuator | | | | |
| | | | Eε²/2 (kJ/m³) | |
| Human skeleton | 0.06 | 25% | 1750 | 1573 |
| muscle | | | | |
| Piezoceramic (PZT) | 7.5 | 0.15% | 8.4 | 1.1 |
| Single crystal PZN-PT | 7.7 | 1.7% | 1113 | 146 |
| Silicone dielectric | 0.01 | 25% | 313 | 135 |
| elastomer | | | | |
| Shape memory alloy | 28 | 5% | 35000 | 5426.4 |
| (Nitinol) | | | | |
| P (VDF-TrFE) | 0.38 | 4% | 304 | 160 |
| electrostrictor | | | | |
| Dehydrofluorinated | 2.5 | 3% | 1125 | 632 |
| PVDF actuator | | | | |

The comparison shows that the present invention exhibits superior volumetric and gravimetric strain energy density surpassing all other actuator materials. The low density and high modulus features of the present invention lead to a gravimetric strain energy density more than 3 times higher than that of previous reported electron-irradiated P(VDF-TrFE), meanwhile providing better mechanical properties in actuator designing. It's conclusive that the reported dehydrofluorinated PVDF that generates giant piezoelectric strain with ultrahigh strain energy density is an excellent candidate for high performance actuator applications.

These results demonstrate that the present invention has significantly improved ferroelectric and piezoelectric properties when compared to previously reported PVDF and its trifluoroethylene copolymers. The FTIR and XRD characterization results suggest that the developed controllable dehydrofluorination method leads to a very high β phase PVDF by largely increasing the effective dipoles contained in the polymer. Excellent ferroelectricity with a remnant polarization of 6.30±0.10 μC/cm² and coercive field of 105 MV/m is determined from the dehydrofluorination induced 13 phase PVDF. Meanwhile, a never reported giant piezoelectric strain coefficient (d₃₃) of −71.84±1.73 pm/V is obtained from PFM testing. Due to the large content of β phase, the large increase of polarization in the dehydrofluorination induced β phase PVDF generates giant piezoelectric strain of up to 3% with a very high strain energy density. Such results show that the present invention is a worthwhile candidate for biomimetic actuators and artificial muscle technologies.

There are abundant uses for materials with ferroelectric (ability to maintain an electric dipole) and piezoelectric (ability to produce an electric charge from external stress) properties. Such materials can be used as sensors, actuators, memory switches, and energy harvesters, among others. As of now, industries using piezoelectric materials frequently employ lead-based ceramics, and there are desires to produce these materials from polymers due to their easier processing, cheaper costs, and lower toxicity. Additionally, piezoelectric polymers have the ability to be incorporated onto flexible electronics and textiles. Polyvinylidene fluoride (PVDF) contains these characteristics when it crystallizes in its beta phase.

### Example 1A

Poly (vinylidene Fluoride) (PVDF) (Kynar 301F) was dissolved in N, N-dimethylformamide (DMF) (BDH, ACS, 99.8%) at room temperature with a concentration of 7 wt. %. Ethylene diamine (ACROS Organics, 99+% extra pure) was added to the prepared PVDF/DMF solution with a concentration of 2 wt. %. The mixture was then placed in a sonicator bath for 30 minutes to achieve uniform solution. After thorough mixing, the solution was maintained at room temperature under ambient atmosphere (room temperature in air at atmospheric pressure) for 8-10 hours. Stirring was used to guarantee the reaction proceeding uniformly within the solution, but was unnecessary for a small volume reaction (solution volume less than 100 ml). After the reaction finished, the solution was poured into deionized water to make the product precipitate from the solution. The product was collected by vacuum assisted filtration after totally precipitation in water. Then the product was washed with deionized water and filtered several times until the filtrate had a neutral pH. The product is finally dried in a convection oven at 80° C. under ambient atmosphere.

### Example 1B

Poly (vinylidene Fluoride) (PVDF) (Kynar 301F) was dissolved in N, N-dimethylformamide (DMF) (BDH, ACS, 99.8%) at room temperature with a concentration of 7 wt. %. Ethylene diamine (ACROS Organics, 99+% extra pure) was added to the prepared PVDF/DMF solution with a concentration of 2 wt. %. The mixture is then kept stirring at room temperature under ambient atmosphere (room temperature in air at atmospheric pressure) for 8 hours. The solution was poured into deionized water after reaction was finished to separate the product. The product PVDf was collected and washed with deionized water and then dried in a convection oven at 80° C. under ambient atmosphere. After completely dried, the product PVDF was dissolved in DMF again at room temperature with a concentration of 20 wt. %. The solution was casted on to a glass substrate and dried a oven at 80° C. under vacuum to produce a PVDF film with a thickness of ˜100 μm. The film was gripped on an Instron universal load frame (Model 5982) and stretched uniaxially with a rate of 10 mm/min at 120° C. The product film was eventually stretched by a elongation of 300%.

### Example 2

Piezoelectric polymers, such as poly (vinylidene fluoride) (PVDF) and its copolymers, can achieve large strains and high working energy density under external electrical fields. Such responsive materials are highly desirable in various applications such as artificial muscles and self-powered wearable devices. Here, a versatile chemical modification is introduced to significantly increase β-phase fraction in PVDF through dehydrofluorination, which provides stable β-phase formation and high piezoelectricity. The efficacy of dehydrofluorination in promoting β-phase formation is demonstrated through molecular simulation and experimental characterization. The dehydrofluorinated PVDF exhibits giant electromechanical coupling with a piezoelectric strain coefficient of d₃₁=32.23±0.19 pm/V. This high coupling coefficient leads to a power density of 21.96 mW/cc in the undrawn PVDF flexible energy harvesters, which is 3.13 times higher than conventionally drawn PVDF. This versatile and scalable method of preparing PVDF polymers with high piezoelectric coupling will broaden its application currently compatible with PVDF homopolymer.

Piezoelectric materials exhibit two-way coupling between mechanical strain and electric charge, originating from an electric dipole existing in certain non-centrosymmetric crystal structures. Ceramics with the perovskite crystal structure, such as lead zirconate titanate and barium titanate, are the most commonly used materials due to their high coupling coefficients. However, there is also a class of polymers that exhibit piezoelectricity due to the molecular structure's formation of polar crystals. Poly(vinylidene fluoride) (PVDF) and its copolymer with trifluoroethylene P(VDF-TrFE) are the most common, offering strong piezoelectricity as well as ferroelectric and pyroelectric properties. Unlike traditional piezoceramics, the synthesis and processing of these polymers does not require sintering at high temperatures and therefore they can be processed using extrusion, making them well suited for capacitors, sensors, and energy harvesters. In addition, PVDF and its copolymer can be cast into flexible thin films, which broaden its application to microelectromechanical systems (MEMS) and wearable devices.

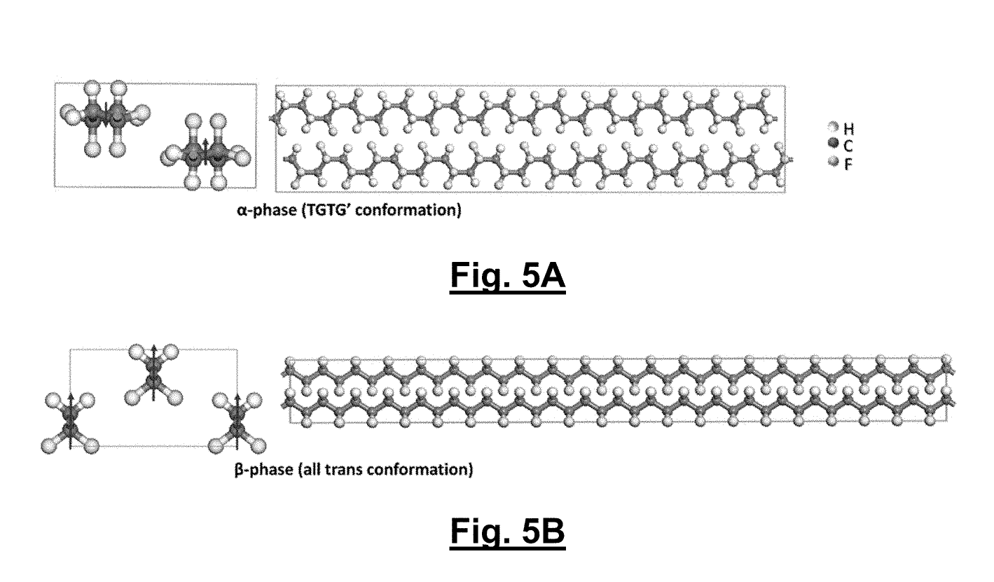

The electromechanical response of PVDF is highly dependent on its crystal structure. PVDF is a semi-crystalline polymer consisting of multiple phases: a paraelectric α-phase, a weak piezoelectric γ-phase, a strong piezoelectric β-phase, and the amorphous phase. Among these phases, the α-phase possesses the lowest conformational potential energy which makes it the most common phase. The polymer chains are in trans-gauche-trans-gauche′ (TGTG′) conformation and stacks anti-parallel in crystal grains, resulting in a total dipole moment of zero as shown in FIG. 5A. However, the most desirable phase in development of electromechanical transducers is the β-phase because it has an all-trans planar chain conformation where every repeat unit functions as an aligned dipole. These planar chains stack parallel in the crystalline region of β-phase, allowing all dipoles to be oriented to the same direction as shown in FIG. 5B. This crystal structure leads to the largest number of aligned permanent dipoles among all PVDF phases and results in better ferroelectric, piezoelectric, and pyroelectric properties. Previously reported methods achieve high planar conformation content in PVDF with an enhanced piezoelectricity through uniaxial stretching, controlling the temperature and evaporation rate, and applying heating processes such as annealing. However, the piezoelectric PVDF produced from these traditional processing methods, especially for the most commonly used mechanical stretching method, remain limited by the high cost processing, the lack of thermal stability and the requirement for the production of a planar film. These limitations restrict the development and utilization of PVDF to its fullest potential as the most common piezoelectric polymer used in flexible actuators and self-powered electronics. As an alternative polymeric piezoelectric material to PVDF homopolymer, Poly (vinylidene fluoride-co-trifluoroethylene) or P(VDF-TrFE), provides an access to stable β-phase and high piezoelectric properties without mechanical treatments. The introduced TrFE comonomers act as molecular defects inducing extra steric hindrance to the polymer chain, leading to a raised conformational potential energy in the α-phase structure. This modification leads to a preferential crystallization into the planar conformation from melt or solvent casting. Despite the complex copolymerization process and largely decreased curie temperature, P(VDF-TrFE) copolymers have attracted even more interest than PVDF homopolymers for applications based on piezoelectricity and ferroelectricity.

Here, a well-controlled dehydrofluorination reaction to chemically modify the crystalline structure of PVDF polymers and facilitate the printing process of these functional materials is introduced. Experimental characterizations are used to establish the efficacy of the dehydrofluorination reaction and study the effective reaction parameters. The formation of β-phase crystal structure and increased piezoelectric coupling through the introduction of double bonds are revealed through experimental characterizations and the working mechanism is explained by molecular simulations. High quality, robust dehydrofluorinated PVDF thin films with the highest reported piezoelectric strain coefficient (d₃₁) are directly printed to demonstrate the compatibility of these materials with modern device fabrication methods. Moreover, the practical application of these printed PVDF films is illustrated in the form of flexible energy harvesting devices. The power density of these energy harvesters is measured to be over three times higher than that of the same devices fabricated from conventional drawn PVDF, which indicates the great potential of the dehydrofluorinated PVDF in the development of electromechanical devices.

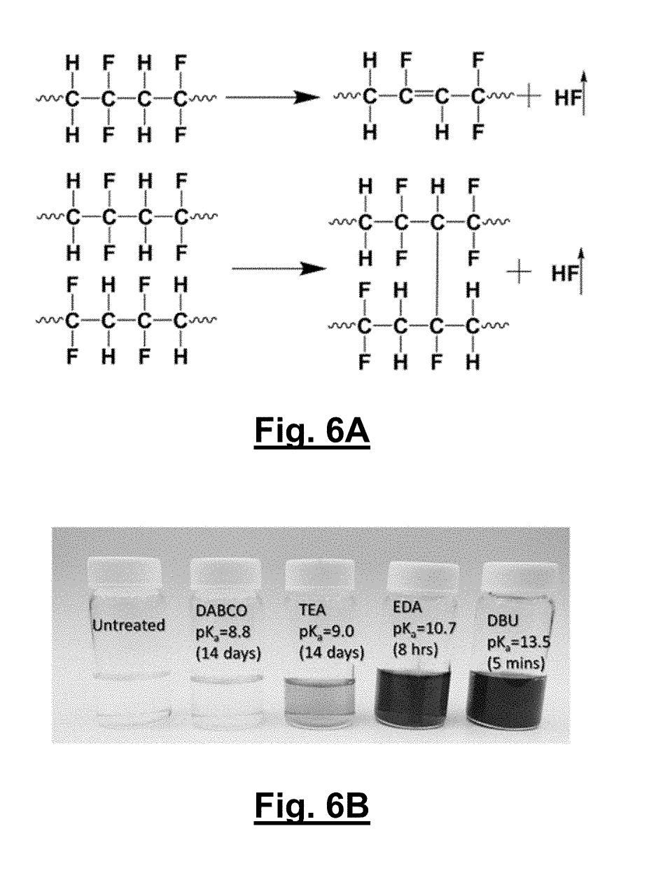

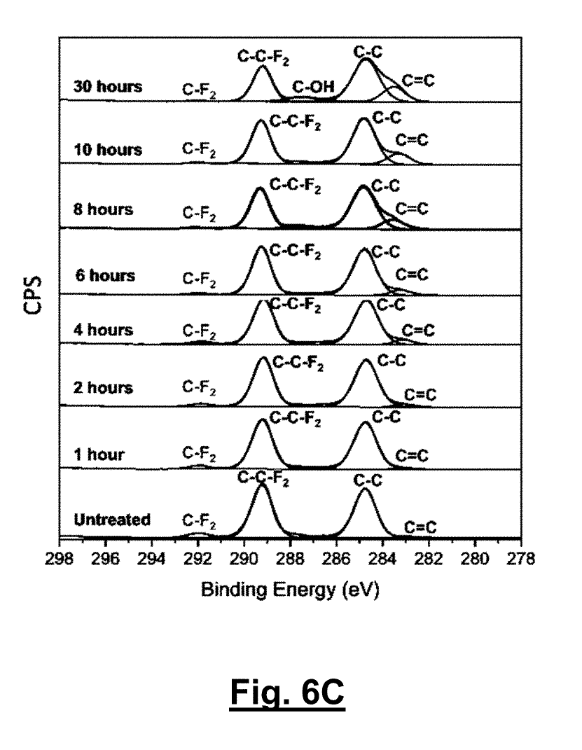

The physical introduction of carbon-carbon double bonds to PVDF is performed through a well-controlled dehydrofluorination reaction. The dehydrofluorination reaction occurs when PVDF is under either a basic or high temperature condition. Through the dehydrofluorination reaction, PVDF is degraded by the removal of hydrogen fluoride (HF) from the polymer's backbone, leaving a carbon-carbon double bond. In some cases, dehydrofluorination also forms crosslinks between the two polymer chains as shown in FIG. 6A. However, in previous research, strong inorganic bases such as sodium hydroxide and potassium hydroxide have been used to induce rapid dehydrofluorination, which usually leads to a highly conjugated system that lacks solubility and exhibits poor dielectric properties. In this case, an increase of undesirable crosslinks and excess degradation occurs, which leads to hindered crystallization of the PVDF and reduced dielectric strength. Weak organic bases are used here as dehydrofluorination agents rather than strong inorganic bases to slow the rate of dehydrofluorination in a PVDF/dimethylformamide (DMF) solution, such that the reaction can be terminated at a desired extent. Primary and tertiary amines including ethylene diamine (EDA), trimethylamine (TEA), 1,4-diazabicyclo[2.2.2]octane (DABCO) and 1,8-diazabicyclo[5.4.0]undec-7-ene (DBU) are investigated regarding their performance as dehydrofluorination agents as shown in FIG. 6B. The extent of dehydrofluorination is controlled by the reaction time and the stoichiometric ratio of dehydrofluorination agent to PVDF repeating units and characterized by means of X-ray photoelectron spectroscopy (XPS). As an example, the XPS C1s spectra of dehydrofluorinated PVDF treated by EDA with various reaction times is shown in FIG. 6C. The XPS spectra of dehydrofluorinated PVDF shows noticeable changes in the surface carbon/fluoride ratio and increased peak intensity of carbon-carbon double bonds. These two parameters can be used to quantify the fraction of dehydrofluorination (% DHF) using the below Equation 1:

$$\% DHF = \frac{\% {C}_{adjust} - \% F}{\% {C}_{adjust}} \times 100 \% \qquad Equation 1$$

where % DHF represents the percentage of dehydrofluorinated VDF units in PVDF, % F is the percentage of fluoride in the tested sample, and % C_{adjust} is the adjusted percentage of carbon in the tested sample, calibrated by the XPS spectra of untreated PVDF, to remove the effects of carbon contaminants. It is found that all investigated amines are able to induce dehydrofluorination of PVDF at room temperature and the rate of dehydrofluorination is determined by their basicity (pKₐ). To reach sufficient fraction of dehydrofluorination, it takes weeks of reaction time for low pKₐ amines such as DABCO (pKₐ=8.8) and TEA (pKₐ=9.0 in DMF), while it only takes hours or few minutes for high pKₐ amines, such as EDA (PKₐ=10.7) and DBU (pKₐ=13.5), using the same stoichiometric ratio of Base to VDF or 1:10. In order to control the % DHF in an accurate and timely manner, EDA is mainly used for dehydrofluorination in this example because it is sufficiently fast to allow dehydrofluorination in a single day while being slow enough to allow the reaction to be quenched at various % DHF levels. After the dehydrofluorination reaction, high quality, robust dehydrofluorinated PVDF thin films are printed through direct write to fabricate films with desired geometry and such that their crystalline structure and electromechanical response can be studied.

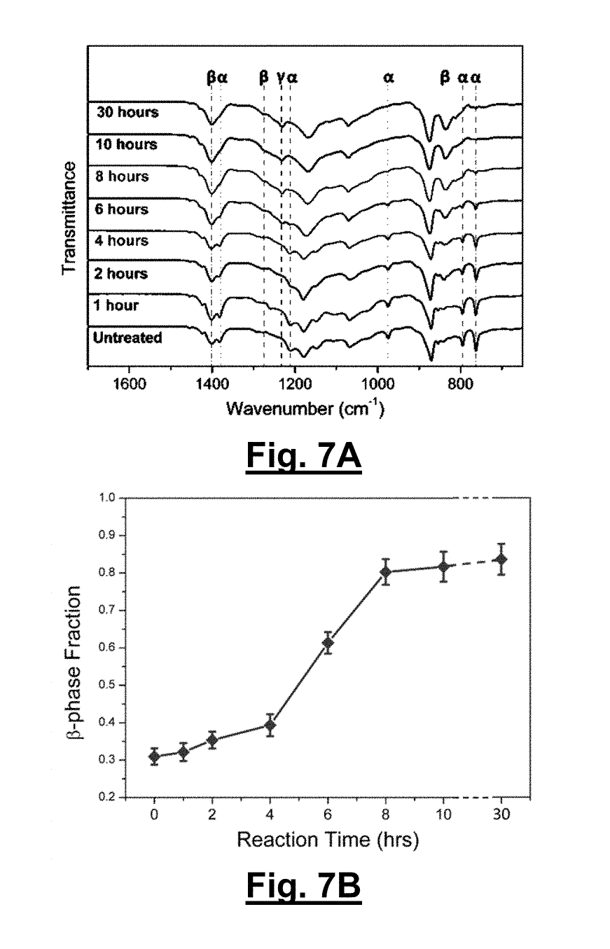

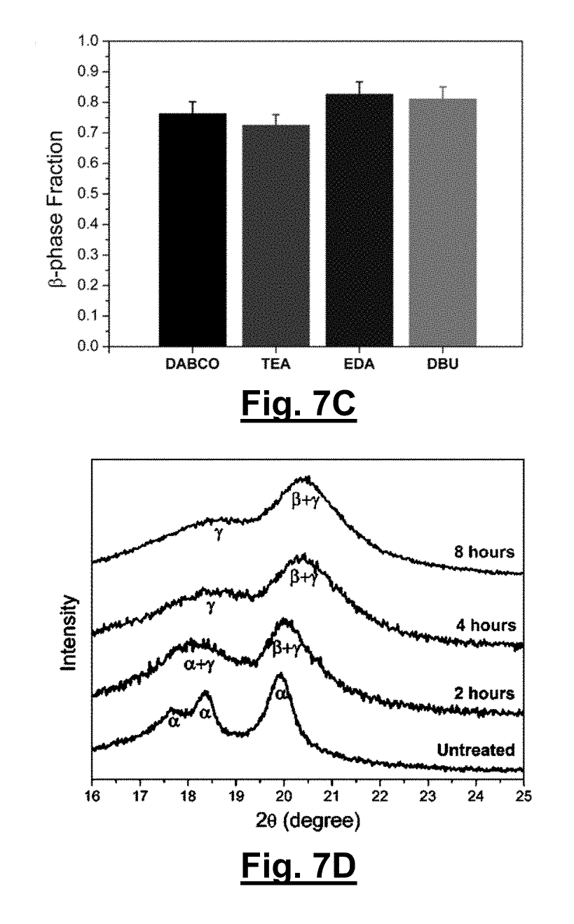

In order to confirm the phase composition changes in PVDF, Fourier transform infrared (FTIR) spectroscopy is performed on untreated PVDF and dehydrofluorinated PVDF films. As shown in FIG. 7A, the FTIR results indicate that β-phase bands (840 cm⁻¹) first appear in the IR spectrum of PVDF treated by EDA for 4 hours and become more significant as the treatment time is increased. Bands of the γ-phase at 1234 cm⁻¹ also increase during the treatment, indicating a gradual transition of chain segment conformation from TGTG′ to trans conformation. Meanwhile, α-phase bands become weaker when treated with EDA for increased time. After 8 hours of DHF treatment with EDA, only a very slight sign of the α-phase is observed. With further increasing reaction time up to 30 hours, the FTIR spectrum shows a similar phase composition when compared to the sample treated for 8 hours. The FTIR results can be used to quantify the β-phase content in PVDF samples based on the Beer-Lambert law. The fraction of α-phase and β-phase in a PVDF specimen is calculated based on the absorption at their characteristic band: 763 cm⁻¹ for α-phase and 840 cm⁻¹ for β-phase. The relative fraction of β-phase, f(β), is calculated using Equation 2:

$$f ( β ) = \frac{{X}_{β}}{{X}_{α} + {X}_{β}} = \frac{{A}_{β}}{( {K}_{840 {cm}^{- 1}} / {K}_{763 {cm}^{- 1}} ) {A}_{α} + {A}_{β}} \qquad Equation 2$$

where X is the degree of crystallinity of the specific phase of PVDF, A_{α} is the absorbance of the α-phase at 763 cm⁻¹, A_{β} is the absorbance of the β-phase at 840 cm⁻¹, and K is the absorption coefficient at the specific wave number (K_{840cm}⁻¹=7.7×10⁴ cm²/mol and K_{840cm}⁻¹=6.1×10⁴ cm²/mol). As shown in FIG. 7B, the calculation results show that the relative fraction of β-phase rapidly increases after a reaction time of 4 hours. After a reaction time of 8 hours, the β-phase fraction also reaches a saturation of 82.31±2.07%. A further increase of % DHF does not show significant improvement of the β-phase fraction in dehydrofluorinated PVDF. Additionally, β-phase formation through dehydrofluorinated PVDF is not limited to the use of EDA as the base. FIG. 7C shows the fraction of β-phase in PVDF induced by different dehydrofluorination agents. The maximum fraction of β-phase, which can be promoted by dehydrofluorination, falls in the range of 74% to 83% of the range of reactants evaluated. Thus, highly β-phase PVDF can be obtained through dehydrofluorination.

While further dehydrofluorination may yield slightly greater β-phase, it can negatively affect the electrical properties of the material. In order to demonstrate the degradation of the film properties, the dielectric strength is measured through a 500 V/sec ramp until failure. After a reaction time of 12 hours, it was found that the dielectric strength of the dehydrofluorinated PVDF significantly decreased. The dielectric strength is a critical parameter for the ferroelectric polymer because it dictates the poling voltage and the maximum drive field when used as an actuator. Thus, when EDA is used as the dehydrofluorination agent and a ratio of EDA:VDF=1:10, the optimum reaction time is found to be 8 hours. The crystalline phase composition of the EDA treated PVDF films is further investigated through X-ray diffraction (XRD) analysis. As illustrated in FIG. 7D, untreated PVDF is dominated by the α-phase (JCPD No. 42-1650). However, as the reaction time is increased to 8 hours the peaks of β-phase (JCPD No. 42-1649) and γ-phase (JCPD No. 38-1638) indicating planar conformation chains grow and become highly prominent in the PVDF. Meanwhile, the relative intensity of the α-phase peaks decrease as the reaction time increases. Similar to the FTIR analysis, the XRD results indicate that the content of β-phase significantly increases when the PVDF homopolymer is dehydrofluorinated. These results therefore demonstrate that the β-phase becomes dominant in PVDF films subjected to a moderate level of dehydrofluorination. Unlike mechanically drawn PVDF, the β-phase in dehydrofluorinated PVDF is induced by chemical modification of the polymer backbone which results in increased torsional stiffness due to the presence of C═C bonds in the backbone which make the helical α-phase less energetically favorable. This unique characteristic leads to uniform mechanical and electrical properties in the dehydrofluorinated PVDF and advantages by way of the versatile and lost-cost manufacturing process.

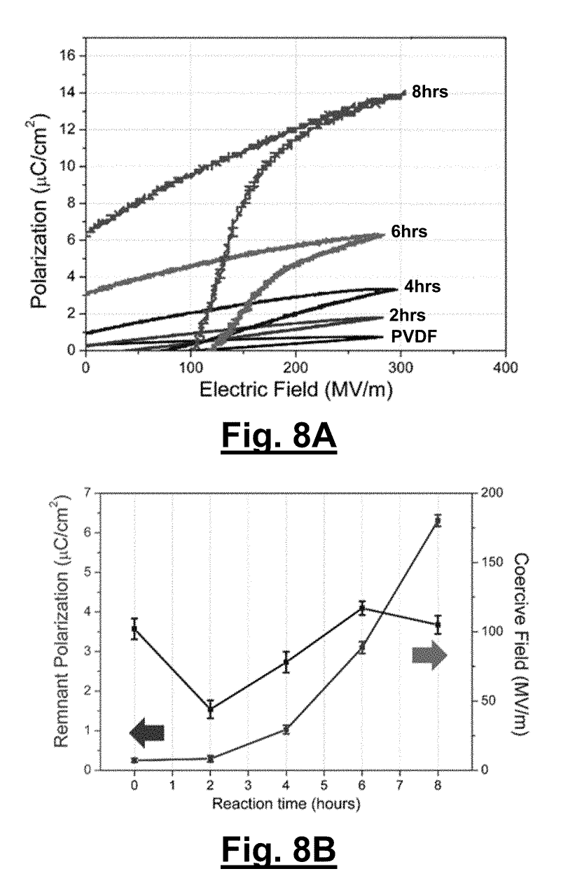

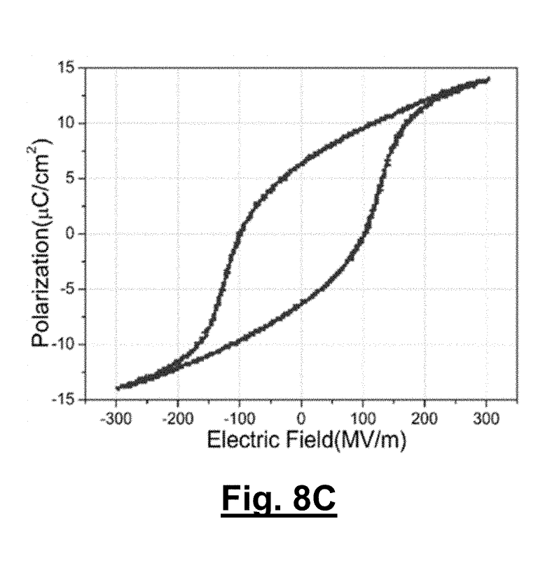

Another method to show the presence of β-phase in dehydrofluorinated PVDF is through the presence of ferroelectric properties which are not present in the typically dominant α-phase. The simplest method to show ferroelectric properties is through the identification of a large remnant polarization. The ferroelectric polarization loops (polarization versus electric field plots) of dehydrofluorinated PVDF with different reaction times, as well as untreated PVDF are shown in FIG. 8A. As the reaction time increases, the polarization of the PVDF changes from mostly dielectric polarization to high ferroelectric polarization with obvious hysteretic behavior. The remnant polarization of PVDF increases from 0.25±0.05 μC/cm² for untreated PVDF to 6.31±0.15 μC/cm² for dehydrofluorinated PVDF (8 hours) as shown in FIG. 8B, and FIG. 8C shows a full ferroelectric hysteresis loop of dehydrofluorinated PVDF with a reaction time of 8 hours. This largely increased ferroelectric behavior is indicative of an increased fraction of β-phase in the dehydrofluorinated PVDF. The correlation between reaction time and ferroelectricity further proves the efficacy of dehydrofluorination as a method to induce the β-phase in PVDF homopolymer. The result of the ferroelectric measurements are in good agreement with the FTIR and XRD analysis, demonstrating that a maximum remnant polarization and β-phase coincide.

To further investigate the mechanism behind dehydrofluorination's efficacy to promote the β-phase conformation in PVDF homopolymer, molecular dynamics simulations are performed on PVDF crystal structures with and without double bonds inserted into the backbone. First, supercell models of both α-phase and β-phase PVDF crystal structures are built according to the crystal parameters reported by previous studies. Each supercell model contains two PVDF chains and each chain contains 20 repeating units. Carbon-carbon double bonds are introduced into the supercell models in a dehydrofluorination manner by replacing VDF units (—CH₂—CF₂—) with fluoroethyne units (—HC═CF—). Three scenarios of different regional chain conformations are built and investigated considering the trans-cis isomerism of double bonds within α-phase and β-phase PVDF: cis conformation double bonds within α-phase (TGTG′-cis), trans conformation double bonds within α-phase (TGTG′-trans), and trans conformation double bonds within β-phase (all trans-trans). The cis conformation double bonds cannot be fitted in the β-phase crystal structure and thus are not considered here. Up to 50% of double bonds are introduced into the supercell models of α-phase and β-phase PVDF according to the three scenarios, replacing the VDF units at random positions. This leads to three series of molecular models of double bonds inserted into the PVDF crystals. Their conformational potential energy can be expressed by Equation 3:

Eₜₒₜₐₗ=E_{bonded}+E_{vdW}+Eₑₛ Equation 3

where E_{bonded} accounts for the potential energy changes from bond stretching, bending, torsion and coupling, E_{vdw} is the van der Waals term, accounting for the intra- and inter-molecular van der Waals interactions, Eₑₛ is the electrostatic term, accounting for the potential energy from electrostatic interactions. To quantify the potential energy, the Condensed-Phase Optimized Molecular Potentials for Atomistic Simulation Studies (COMPASS) force field is used in this simulation. The parameters for valence and van der Waals terms, and atomic partial charges are assigned by the force field as incorporated in the Materials Studio software. Initially, the simulation yields an energy difference of 19.848 kcal/mol between α-phase and β-phase conformation of pure PVDF homopolymer for this supercell model. It shows that although the van der Waals term of β-phase PVDF yields lower energy than α-phase, the electrostatic term is much higher than that of α-phase because the parallel aligned dipoles are not energetically preferable in intramolecular interactions. When carbon-carbon double bonds are introduced to the system, the van der Waals terms of the α-phase (both TGTG′-cis and TGTG′-trans model) increase significantly, indicating largely increased steric effects. Meanwhile the van der Waals term of β-phase PVDF (all trans-trans model) decreases, because the sp2 hybridized double bonds reduce the out-of-plane steric effects in all-trans conformation. The energy difference between the electrostatic terms of the three models is unchanged at a low fraction of double bonds (<30%) and decreases at a high fraction of double bonds. This leads to a lower conformational potential energy in the β-phase than the α-phase after a certain fraction of double bonds is introduced to the PVDF backbone. Specifically, the total conformational potential energy of the all trans-trans model containing 10% double bonds is 2.451 kcal/mol lower than TGTG′-cis model and 26.404 kcal/mol lower than TGTG′-trans model with the same fraction of double bonds. The energy differences are further increased with an increasing fraction of double bonds. At a double bonds fraction of 25%, the energy difference becomes 22.971 kcal/mol between all trans-trans model and TGTG′-cis model, larger than the initial energy differences between α-phase and β-phase PVDF homopolymer. This large difference between the two conformations indicates that the PVDF containing double bonds exhibit a preferential crystallization into the β-phase from a melt or during solvent casting. The energy difference continues to increase when a large fraction of double bonds are introduced, implying that the β-phase formation will be preferential once a sufficient extent of dehydrofluorination is induced. As a validation of this simulation, similar trends of energy changes are found in the molecular simulation of P(VDF-TrFE) copolymer, which also exhibits a change in preferential crystalline phase after a certain fraction of co-monomer is introduced. The crystallization behavior of dehydrofluorinated PVDF predicted by this molecular simulation method is consistent with the characterization results identified in the experimental results. A similar optimum dehydrofluorination extent exists when the β-phase formation becomes energy preferential. The efficacy of the dehydrofluorination method to promote β-phase formation is thus proven through both theoretical and experimental approaches.

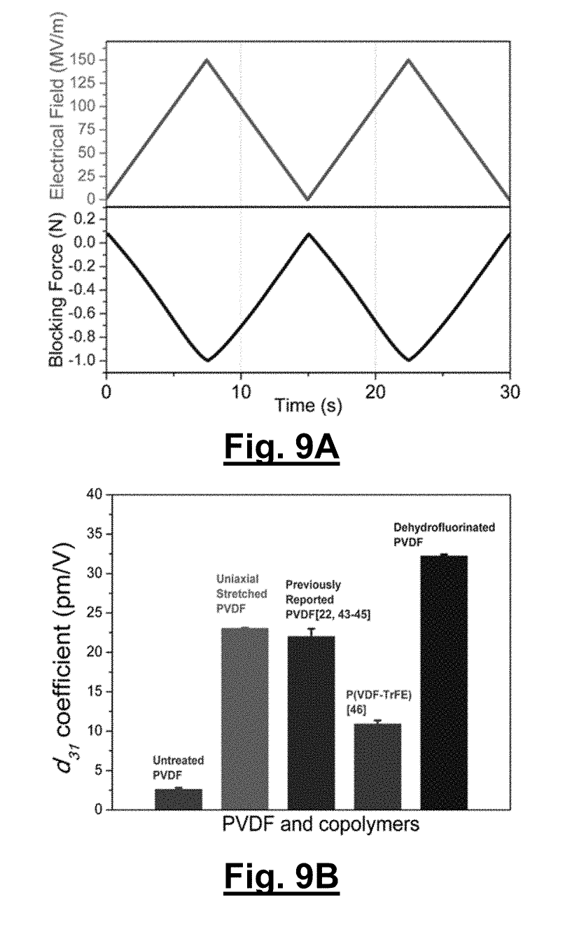

Given the increased fraction of β-phase and the strong ferroelectric properties, the dehydrofluorinated PVDF should also exhibit strong piezoelectric coupling. This is evaluated by characterizing its piezoelectric actuation performance through a blocked force measurement. Blocked force is the force generated by an actuator at zero displacement. The measurement requires the actuator to work against a load with infinite stiffness and indicates the maximum force the actuator can generate under a specific voltage. Once subjected to electric fields, PVDF will generate a contractive strain along the field direction because of its negative piezoelectric strain coefficient d₃₃, and simultaneously it will generate expansive strains on directions perpendicular to the field. Therefore, the blocking force of PVDF films on the longitude direction can be conveniently measured while electric field is applied across the thickness. In order to determine the blocking force of the PVDF films on the longitude direction, a rectangular film is fixed in a universal load frame while an electric potential difference is applied across film's thickness. Therefore, the amount of generated force by the PVDF film at zero displacement is precisely measured using a load cell. Bipolar triangular electrical signal with an amplitude of 150 MV/m is applied on the dehydrofluorinated PVDF sample (8 hour EDA reaction for maximum β-phase fraction) and the responsive forces are measured by the load cell. It should be noted that the negative values of measured force are due to the expansion of PVDF samples, while the positive values indicate contraction. Hysteresis in the change of blocking force directions along with the change of external field is observed, corresponding to the piezoelectric domain switching behavior. The domain repolarization behavior can be observed more obviously by the blocking force versus electric field plot, which shows a typical piezoelectric butterfly loop behavior. To more accurately capture the maximum blocking force the dehydrofluorinated PVDF samples can generate, unipolar triangular electrical signals with a peak value of 150 MV/m and different frequencies are also applied to the samples. A maximum blocking force value of 1.011 N is observed at a signal frequency of 0.01 Hz as shown in FIG. 9A, which is approximately 14000 times of the weight of the tested sample (tested sample mass ˜7.19 mg equals weight of 7.05×10⁻⁵ N). Additionally, the results of this measurement provide sufficient data to calculate the lateral piezoelectric strain coefficient d₃₁, which indicates the electromechanical interaction ability of PVDF on the direction perpendicular to the applied electrical field. Derived from the constitutive equation of inverse piezoelectric effect, the d₃₁ coefficient of tested dehydrofluorinated PVDF films can be approximately calculated by following equation (Equation 4):

$${d}_{31} = - \frac{{F}_{max}}{A \cdot {E}_{y} \cdot E} \qquad Equation 4$$

where Fₘₐₓ is the maximum blocking force, A is the cross-section area of the sample, E_{y} is the Young's modulus, and E is the applied electrical field. As shown in FIG. 9B, the calculated d₃₁ coefficient of dehydrofluorinated PVDF is 32.23±0.19 pm/V, higher than any other previously reported d₃₁ values on PVDF, which were in the range of 21 pm/V to 23 pm/V. The d₃₁ coefficient of untreated PVDF and conventional drawn PVDF are also measured by same method for comparison purposes. The conventional drawn PVDF yields a d₃₁ of 23.05±0.20 pm/V, close to the reported value on the product datasheet. The large d₃₁ coefficient and blocking force of the dehydrofluorinated PVDF films indicate that the increased β-phase fraction through dehydrofluorination leads to ultrahigh piezoelectricity, providing them great potential as flexible sensing, actuating, and energy harvesting materials.

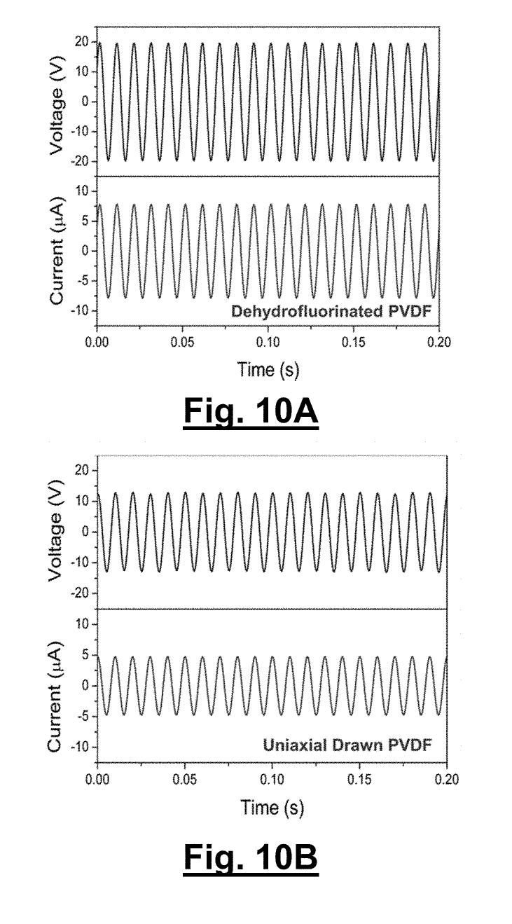

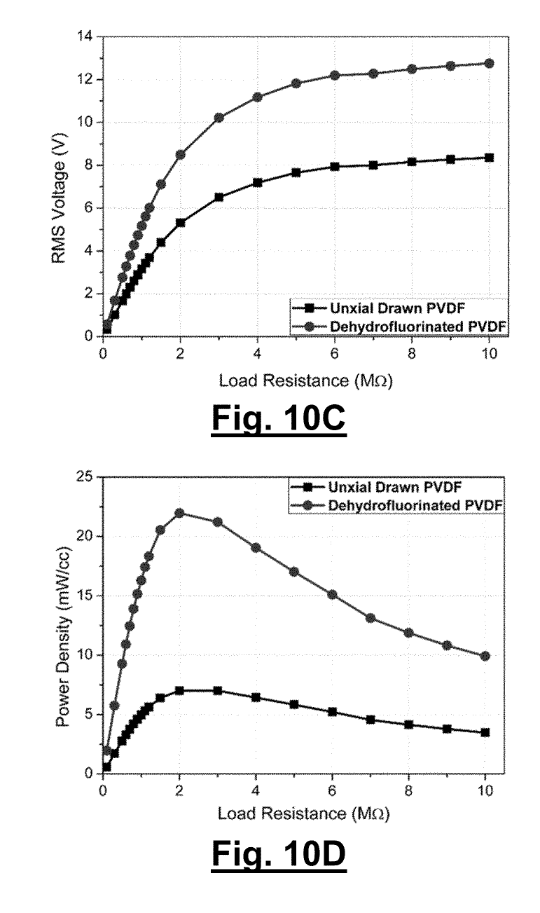

The high d₃₁ coefficient indicates the polymer would be ideal for application in sensing and energy harvesting, and therefore, to demonstrate utility of this material, flexible energy harvesters are fabricated and evaluated using a dynamic mechanical analyzer (DMA). The piezoelectric energy harvesting devices are fabricated from dehydrofluorinated PVDF thin films that are prepared by casting a PVDF/DMF solution onto a glass substrate. The films are then poled by corona poling at an elevated temperature and gold is subsequently sputtered on both surfaces to function as top and bottom electrodes. Energy harvesting devices consisting of conventional uniaxial drawn PVDF (obtained from TE Connectivity) and uniaxial drawn dehydrofluorinated PVDF are also fabricated for comparison purpose. The devices are tested on a DMA system using film tension clamps and are subjected to unidirectional tensile loading under a small constant maximum strain (set at 0.5%) at various frequencies. Biased open circuit AC voltage and short circuit current are generated from the device and measured by an electrometer. A maximum peak to peak voltage of 40.26 V with an RMS value of 13.97 V is obtained when the dehydrofluorinated PVDF devices are subjected to 0.5% strain harmonic excitation at a frequency of 100 Hz as shown in FIG. 10A. A high peak to peak short circuit current of 15.74 μA with an RMS value of 5.53 μA is also measured under the same condition as shown in FIG. 10A. For uniaxial drawn PVDF devices, an open circuit RMS voltage of 9.00 V and short circuit RMS current of 3.34 μA are measured under same conditions as shown in FIG. 10B. The dehydrofluorinated PVDF devices show over 55% larger voltage and current response compared to conventional PVDF devices. To measure the power density of these devices, the AC voltage signal from the energy harvesting devices are measured across a series of load resistors ranging from 1 MΩ to 10 MΩ. The AC power generated is calculated from the RMS voltage value and the electrical resistance. A peak AC power of 36.06 μW is obtained from the DHF-PVDF at an optimum load resistance of 2 MΩ as shown in FIG. 10C, which corresponds to a peak power density of 21.96 mW/cc under a 0.5% maximum strain at 100 Hz as shown in FIG. 10D. For the conventional PVDF energy harvester, the peak AC power across the load resistor of 2 MΩ is only 14.09 μW from same excitation at 0.5% maximum strain at 100 Hz, leading to a calculated peak power density of only 7.01 mW/cc. The power density from the dehydrofluorinated PVDF energy harvester is 3.13 times higher than the peak power density of a conventional PVDF energy harvester and considerably higher than other previously reported PVDF energy harvesters. It should be noted that the high energy harvesting performance and voltage generation capacity of the dehydrofluorinated PVDF are observed across different frequencies and resistive loads. The high output power from the dehydrofluorinated PVDF films further shows the large intrinsic electromechanical response of this piezoelectric polymer and implies the efficiency of the dehydrofluorination process. Utilizing this process eliminates the need for mechanical drawing to induce the formation of β-phase in PVDF polymers and make these functional polymers suitable for material integration using modern additive manufacturing techniques.

In summary, a simple versatile approach for synthesis of high piezoelectric β-phase PVDF through well-controlled dehydrofluorination is introduced. The efficacy of this method is established through experimental characterizations and molecular simulations. The newly developed dehydrofluorinated PVDF films show significantly high piezoelectric properties compared to previously reported PVDF and its trifluoroethylene copolymers because of the high fraction of β-phase content and effective dipoles in the polymer. This preferential crystallization behavior is explained by the potential energy simulation of the dehydrofluorinated PVDF. Moreover, the piezoelectric strain coefficient (d₃₁) of the dehydrofluorinated PVDF is measured to be 32.23±0.19 pm/V, which is the highest ever reported coefficient for PVDF polymers. The giant d-coefficient indicates the sensing and energy harvesting potential of the material. Therefore, to show the polymer's capacity for energy conversion, power measurements were performed under dynamic excitation. The dehydrofluorinated PVDF is shown to yield a power density 3.13 times higher than commercial drawn PVDF when subjected to a cyclic tensile load with 0.5% strain amplitude. These results demonstrate that the dehydrofluorinated PVDF has excellent potential for low-cost, flexible, and printable piezoelectric materials. Furthermore, the improved thermal stability and eliminated need for mechanical drawing would enable a simple route towards additive manufacturing of PVDF materials with high polar phase content, leading to a wide range of practical applications for piezoelectric polymers.

### Example 3

Method

3 g poly(vinylidene fluoride) (PVDF; Kynar 401F) is dissolved in dimethyl acetamide (DMAc) to form a solution. 21 g of 1,8-diazabicyclo[5,4,0]undec-7-ene (DBU) is added to the solution to form a reaction solution. The reaction solution is incubated for 12 hours at room temperature. Reaction products are recovered by filtering, washing, and drying at 110° C.

Results

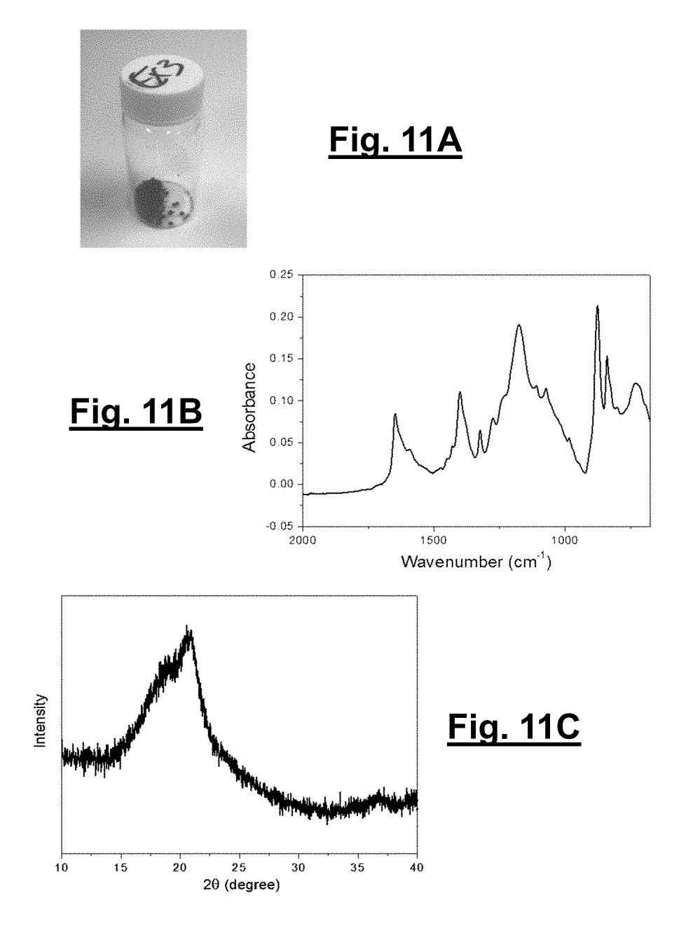

As shown in FIG. 11A, the treated PVDF became black solid and completely lost solubility in common PVDF solvents (such as DMF, DMAc, and DMSO). As shown in FIG. 11B, FTIR indicated the presence of β-phase (1275 cm⁻¹ and 840 cm⁻¹), as well as obvious C═C formation (1647 cm⁻¹, 1324 cm⁻¹ and 730 cm⁻¹). As shown in FIG. 11C, XRD showed the PVDF chains left in the product are majorly in β and γ phase (18.5° and 20.5°). However, the crystallinity of the treated PVDF is very low (indicated by the low intensity and wide peak). This is because the C═C bonds interrupted the crystalline regions of PVDF. As a result, the reaction product does not exhibit melt flow behavior.

Because the treated PVDF lost solubility in most solvents, it is not possible to cast films from these products and utilize them as piezoelectrics. Furthermore, the samples exhibited electrical conductivity and therefore cannot be used as a piezoelectric material even though the crystal structure shows a small degree of beta phase.

### Example 4

Method

1.5 g PVDF is dissolved in DMAc to form a solution. 10.7 g of DBU is added to the solution to form a reaction solution. The reaction solution is refluxed for 3 hours. Products are recovered by filtering, washing, and drying at 110° C.

Results

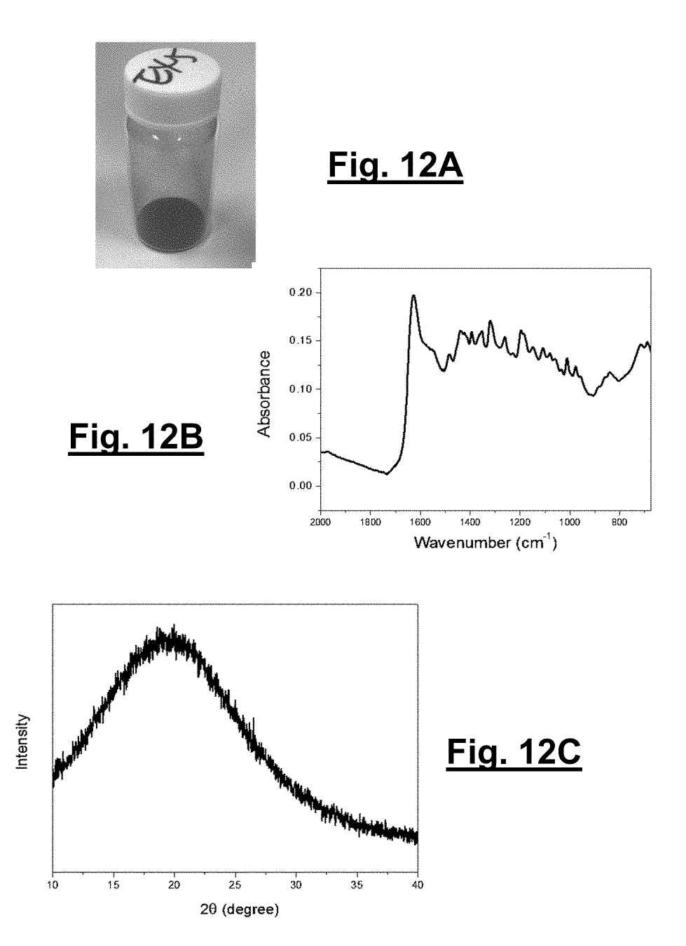

As shown in FIG. 12A, the product is fine powder of black solids and completely lost solubility in common PVDF solvents (such as DMF, DMAc, and DMSO). As shown in FIG. 12B, FTIR indicated a high degree of carbonization, while the characteristic peaks of PVDF disappeared. As shown in FIG. 12C, XRD shows the product is in an amorphous phase. This is because of a high degree of dehydrofluorination. No piezoelectric phases are found in the product and the product does not exhibit melt flow behavior.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A method for synthesizing a piezoelectric material, the method comprising:
dehydrofluorinating a fluoropolymer precursor by incubating the fluoropolymer precursor in the presence of a base, wherein the fluoropolymer precursor comprises poly(vinylidene fluoride) or a copolymer of vinylidene fluoride; and
isolating an at least partially dehydrofluorinated fluoropolymer solid having β-phase and that exhibits melt flow processability at a temperature of greater than or equal to about 150° C.,
wherein the at least partially dehydrofluorinated fluoropolymer solid is capable of forming a solid piezoelectric fluoropolymer material having β-phase in an amount sufficient to exhibit a piezoelectric strain coefficient d₃₁ absolute value of greater than or equal to about 25 pm/V.

2. The method according to claim 1, wherein during the dehydrofluorinating, the fluoropolymer precursor and the base are combined with a solvent selected from the group consisting of N-methyl pyrrolidone (NMP), dimethylsulfoxide (DMSO), N,N-dimethylformamide (DMF), methyl ethyl ketone (MEK), tetrahydrofuran (THF), N,N-dimethylacetamide (DMAc), and combinations thereof.

3. The method according to claim 2, wherein the dehydrofluorinating forms an at least partially dehydrofluorinated reaction product present in the solvent, and the isolating further comprises precipitating the at least partially dehydrofluorinated reaction product from the liquid admixture and recrystallizing the at least partially dehydrofluorinated reaction product to form the at least partially dehydrofluorinated fluoropolymer solid.

4. The method according to claim 1, wherein during the dehydrofluorinating, the fluoropolymer precursor is a solid fluoropolymer precursor that is suspended in a liquid admixture comprising the base.

5. The method according to claim 4, wherein the dehydrofluorinating forms the at least partially dehydrofluorinated fluoropolymer solid from the solid fluoropolymer precursor, and the isolating further comprises removing the at least partially dehydrofluorinated fluoropolymer solid from the liquid admixture.

6. The method according to claim 5, wherein the removing comprises at least one of centrifuging and decanting.

7. The method according to claim 1, further comprising:
resuspending or dissolving the at least partially dehydrofluorinated fluoropolymer solid in a liquid; and
forming a solid piezoelectric fluoropolymer material that exhibits a piezoelectric strain coefficient d₃₁ absolute value of greater than or equal to about 25 pm/V by removing at least a portion of the liquid from the resuspended or dissolved at least partially dehydrofluorinated fluoropolymer solid.

8. The method according to claim 7,
wherein the forming comprises performing a process selected from the group consisting of doctor blading, spin casting, printing, injection molding, slot die casting, micro gravure, extrusion, solution casting, spray coating, dip coating, and combinations thereof.

9. The method according to claim 1, further comprising:
forming a solid piezoelectric fluoropolymer material having β-phase and exhibiting a piezoelectric strain coefficient d₃₁ absolute value of greater than or equal to about 25 pm/V by three-dimensional printing,
wherein the three-dimensional printing comprises heating the at least partially dehydrofluorinated fluoropolymer solid to a temperature of greater than or equal to about 150° C. and directing the heated solid piezoelectric fluoropolymer material onto a target.

10. The method according to claim 9, wherein the piezoelectric fluoropolymer material comprises greater than or equal to about 50 volume % β-phase.

11. The method according to claim 9, wherein the piezoelectric fluoropolymer material has a remnant polarization of greater than or equal to about 1 μC/cm².

12. The method according to claim 1, wherein the base is a volatile base and the dehydrofluorinating is performed in a liquid admixture comprising the fluoropolymer precursor, the volatile base, and a solvent, the fluoropolymer precursor being dissolved or suspended in the solvent, and the isolating comprises, after the dehydrofluorinating, directly casting the liquid admixture into a predetermined shape and evaporating the solvent and the volatile base, wherein the at last partially dehydrofluorinated fluoropolymer solid forms as a solid piezoelectric fluoropolymer material having the predetermined shape, and having β-phase in an amount sufficient to exhibit a piezoelectric strain coefficient d₃₁ absolute value of greater than or equal to about 25 pm/V.

13. The method according to claim 1, wherein the base is an inorganic base.

14. The method according to claim 1, wherein the base is an organic base.

15. The method according to claim 1, wherein the dehydrofluorinating is performed until greater than or equal to about 2 vol. % to less than or equal to about 25 vol. % of the fluoropolymer precursor is dehydrofluorinated.

16. A method of making a piezoelectric component, the method comprising:
heating an at least partially dehydrofluorinated fluoropolymer solid by applying heat at a temperature of greater than or equal to about 150° C. to create a flowable piezoelectric fluoropolymer, wherein the at least partially dehydrofluorinated fluoropolymer solid is isolated from a reaction between at least one of a poly(vinylidene fluoride) and a copolymer of vinylidene fluoride and a base; and
forming the flowable piezoelectric fluoropolymer into a three-dimensional piezoelectric component having β-phase in an amount sufficient to exhibit a piezoelectric strain coefficient d₃₁ of greater than or equal to about 25 pm/V.

17. The method according to claim 16, wherein the at least partially dehydrofluorinated fluoropolymer solid comprises greater than or equal to about 50 volume % β-phase.

18. The method according to claim 16, wherein the heating and the forming are performed during three-dimensional printing.

19. The method according to claim 16, wherein the forming comprises injecting the flowable piezoelectric fluoropolymer into a mold.

20. The method according to claim 16, further comprising incorporating the three-dimensional piezoelectric component as a component into a power source, a sensor, an actuator, a frequency standard, a motor, or a photovoltaic device.

21. A method of making a piezoelectric component, the method comprising:
obtaining a at least partially dehydrofluorinated fluoropolymer solid isolated from a dehydrofluorination reaction between a base and at least one of a poly(vinylidene fluoride) and a copolymer of vinylidene fluoride;
resuspending or dissolving the at least partially dehydrofluorinated fluoropolymer solid in a liquid to form a liquid comprising the at least partially dehydrofluorinated fluoropolymer; and
forming the liquid comprising the at least partially dehydrofluorinated fluoropolymer into a solid piezoelectric component comprising a piezoelectric fluoropolymer having greater than or equal to about 50 volume % of β-phase and a remnant polarization of greater than or equal to about 1 μC/cm² by removing at least a portion of the liquid from the liquid comprising the at least partially dehydrofluorinated fluoropolymer.

22. The method according to claim 21, wherein the forming comprises performing a process selected from the group consisting of doctor blading, spin casting, printing, injection molding, slot die casting, micro gravure, extrusion, solution casting, spray coating, dip coating, and combinations thereof.
